(19) United States
(12) Patent Application Publication
(10) Pub. No.: US 2026/0271657 A1
(43) Pub. Date: Sep. 10, 2026

(54) AUTOMATED MACHINE LEARNING WITH SPATIAL SENSOR

(71) Applicant: Lam Research Corporation, Fremont, CA (US)

(72) Inventors: Kapil Umesh Sawlani, West Linn, OR (US); Patging John Elsworth Martin, Portland, OR (US); Paul M. Franzen, West Linn, OR (US); Rafsan Rabbi, Tualatin, OR (US); Seshasayee Varadarajan, Lake Oswego, OR (US)

(73) Assignee: Lam Research Corporation, Fremont, CA (US)

(21) Appl. No.: 19/165,552

(22) PCT Filed: May 28, 2024
(86) PCT No.: PCT/US2024/031298

§ 371 Date: Sep. 15, 2025

Related U.S. Application Data
(60) Provisional application No. 63/504,976, filed on May 30, 2023.

(51) Int. Cl. H10P 72/00

(52) U.S. Cl. CPC H10P 72/0462; H10P 72/0606

(57) ABSTRACT

Described herein is a process system comprising a process module and at least one spatial sensor. In at least one implementation, process module comprises a pedestal, and a viewport window within a wall of the process module. In at least one implementation, a spatial sensor is external to the process module and adjacent to the viewport window. In at least one implementation, a computing device is electronically coupled to the spatial sensor. In at least one implementation, the pedestal is within a field of view of the spatial sensor.

### CLAIM FOR PRIORITY

This application claims priority to U.S. Provisional Patent Application No. 63/504,976, filed on May 30, 2023, titled “Automated Machine Learning with Spatial Sensor,” which is incorporated by reference in its entirety for all purposes.

### BACKGROUND

Process systems are used to perform treatments such as deposition and etching of film on semiconductor wafer substrates. Such process systems may comprise one or more process modules in which chemical vapor deposition (CVD), including plasma-enhanced chemical vapor deposition (PECVD) and atomic layer deposition (ALD) processes can be performed. Process systems may need parts replacement or calibration periodically. Changes of currently executed process recipes or addition of new processes may require repositioning of wafers or some process components within a process module. Currently, teaching system software to perform wafer transfer operations is primarily a manual task. Field engineers may not have sufficient experience to perform machine teaching tasks efficiently. Consequently, the teaching process can be slow and prone to human error. As fleets of process equipment are employed globally, deployment of field engineers to perform such manual machine teaching tasks becomes increasingly expensive and difficult.

### BRIEF DESCRIPTION OF THE DRAWINGS

FIG. 1 illustrates a cross-sectional view of a process module, in accordance with at least one implementation.

FIG. 2A illustrates a profile view of a process system comprising edge-viewing spatial sensors, in accordance with at least one implementation.

FIG. 2B illustrates a profile view of a process system comprising at least one overhead-viewing spatial sensor, in accordance with at least one implementation.

FIG. 2C illustrates a plan view of a process system, in accordance with at least one implementation.

FIG. 2D illustrates a plan view of a process system during a machine learning event, according to at least one implementation.

FIG. 3A illustrates a profile view of a process system comprising a vacuum transfer module and a process module like process modules shown in FIGS. 2A-2D, according to at least one implementation.

FIG. 3B illustrates a profile view of the process system shown in FIG. 3A after a wafer transfer operation and subsequent plasma-enhanced chemical vapor deposition (PECVD) process has been initiated, in accordance with at least one implementation.

FIG. 3C illustrates a frontal profile view of a slit valve comprising a spatial sensor mounted on a slide door of the slit valve, in accordance with at least one implementation.

FIG. 3D illustrates a rear profile view of the slit valve shown in FIG. 3C, in accordance with at least one implementation.

FIG. 3E illustrates a frontal profile view of the slit valve shown in FIG. 3C, shown in an open position, according to at least one implementation.

FIG. 3F illustrates an overhead view of a process system incorporating a spatial sensor 342 mounted on a slit valve between a vacuum transfer module and a process module, in accordance with at least one implementation.

FIG. 3G illustrates orthogonal perspective views of a wafer mounted on a pedestal, as captured by orthogonally oriented spatial sensors, in accordance with at least one implementation.

FIG. 3H illustrates a profile view of process system in a first loading operation preparing to transfer a wafer from a vacuum transfer module to a process module, in accordance with at least one implementation.

FIG. 3I illustrates a profile view of the process system shown in FIG. 3H in a second loading operation, in accordance with at least one implementation.

FIG. 3J illustrates a profile view of the process system shown in FIG. 3H and FIG. 3I, in a third loading operation, in accordance with at least one implementation.

FIG. 3K illustrates a flow chart summarizing an exemplary sequence of loading and centering operations for robot teaching, in accordance to at least one implementation.

FIGS. 4A-4D illustrate a series of video capture images of a PECVD process captured by an edge-viewing spatial sensor, in accordance with at least one implementation.

FIG. 5 illustrates a plot tracing time evolution of particle buildup on a wafer edge or on the edge of a chuck, in accordance with at least one implementation.

FIG. 6 shows a flow chart summarizing an exemplary method to determine a particle size threshold for initiating a clean cycle, in accordance with at least one implementation.

FIG. 7 illustrates a schematic diagram of an exemplary process system in accordance with at least one implementation.

FIG. 8 illustrates a hardware block diagram of a process control system for operation of process systems described herein, such as the process system shown in FIG. 7, in accordance with at least one implementation.

FIG. 9 illustrates a software block diagram showing an exemplary organization and hierarchy of system software for autonomous teaching and operation of process systems described herein, in accordance with at least one implementation.

FIG. 10 illustrates a flow chart summarizing an exemplary method for performing a wafer transfer into a process module, in accordance with at least one implementation.

FIG. 11 illustrates a flow chart summarizing an exemplary method for performing an automatic wafer centering (AWC) operation within a process module, in accordance with at least one implementation.

FIG. 12 illustrates a processor system with machine-readable storage medium having instructions that when executed cause a processor to actuate motorized components of a process system, such as the process system illustrated in FIG. 7, in accordance with at least one implementation.

### DETAILED DESCRIPTION

At least one implementation describes an apparatus and methods for automated machine learning for training process system software to perform automatic process supervision tasks. Such tasks may include wafer transfer and handoff, as well as monitoring deposition chamber conditions for cleanliness and signaling or triggering automated clean cycles when necessary. film growth during deposition processes for particle contamination., In at least one implementation, automated machine learning apparatus and methods can provide significant time savings for training process tool software to perform new or modified processes. In at least one implementation, the apparatus and methods described herein can also be employed when calibrating new or replaced components in process systems. In at least one implementation, the apparatus and methods described herein replace conventional human-supervised pendant teaching machine learning methods. In at least one implementation, the apparatus and methods described herein monitor cleanliness of a chamber and automatically sets reminders for cleaning cycles or performs cleaning of chamber automatically. As such system yield is enhanced because of more controlled deposition of particles from a cleaner chamber.

In at least one implementation, spatial sensors may be arrayed in and around a process module to capture video data and stream it to a computing device associated with a process system. In at least one implementation, spatial sensors are video cameras. In at least one implementation, video data may be parsed and analyzed by machine vision and/or machine learning software stored on or accessed by a computing device. Spatial sensors are analogous to human eyes, whereby spatial sensors capture visual images to be used for automated machine learning and process supervision.

In at least one implementation, a method is disclosed for automated machine learning by teaching to a robot arm to bring a wafer into a process chamber and place the wafer onto a chuck on a pedestal. This task may be performed when a new process is introduced, or a current process is modified, for example. In at least one implementation, similar automated machine learning may be performed when process tool equipment is new or replaced and may call for a calibration procedure. For example, semiconductor processing equipment, such as a chuck, pedestal, showerhead, robot arm or spindle, may be partially or wholly replaced because of damage or age. New equipment may have different dimensions or placement within the chamber relative to the old equipment. Wafer transfer tasks that may be calibrated for a prior configuration may have to be re-calibrated. For example, automatic wafer centering may require learning of new pedestal coordinates for accurate handoff of a wafer by a robot arm to a pedestal. Another example is a change in process recipe. For example, a new or modified process recipe may call for a different pedestal z-height. For wafer handoff, a robot arm transferring wafers to the pedestal may be taught the new z-height position. Conventionally, the recalibration task is performed by a technician or engineer with a teach pendant communicating with system software of the process tool. The recalibration performed by conventional pendant teaching may be tedious, prolonged, and expensive. In accordance with at least one implementation presented herein, wafer transfer teaching by automated machine learning may be significantly more rapid and efficient in comparison with conventional pendant teaching.

In at least one implementation, spatial sensors are configured to monitor movement of a robot arm transferring a wafer from outside a process chamber to a pedestal within the process chamber. In at least one implementation, visual data captured by spatial sensors may be transferred to a machine vision module within system software operating the process tool. In at least one implementation, raw visual data may be processed and analyzed by image processing algorithms within the machine vision module. In at least one implementation, movement of a robot arm may be tracked by determining positional coordinates of robot arm by image processing software, for example. In at least one implementation, supervisory module may keep track of positional coordinates of moving robot arm and perform corrections of its trajectory to arrive at a predetermined destination for wafer handoff. In at least one implementation, a machine learning module may be taught a set of data corresponding to correct robot arm trajectory coordinates from supervisory module. In at least one implementation, machine learning module may store learned coordinates as training data for future autonomous wafer transfer operations.

In at least one implementation, a method is disclosed for determining a particle size limit for initiating a clean cycle of a process module. In at least one implementation, the method is based on the apparatus described above. In at least one implementation, films may build up over several process cycles on non-target surfaces within a process module, such as a showerhead. As deposits may thicken over time, particles may flake off such deposits during a deposition process and may land on a wafer under process. In at least one implementation, the disclosed method comprises real time monitoring of film growth by one or more spatial sensors. In at least one implementation, one or more spatial sensors is/are positioned to view the wafer edge on. In at least one implementation, one or more spatial sensors is/are positioned to view the wafer from overhead, or from an oblique angle.

In at least one implementation, real time video data comprising image frames of the growth process may be streamed to a computing device. In at least one implementation, the computing device may execute an algorithm that is operable to analyze the images to detect presence of particles by machine vision software. In at least one implementation, the algorithm measures surface roughness of a growing film during a deposition process by image analysis. In at least one implementation, the algorithm determines particle size by measuring surface roughness and compares an average particle size to a threshold value. In at least one implementation, a clean cycle is initiated or indicated to users if the average particle size meets or exceeds the threshold.

In the following description, well-known methods and devices are shown in block diagram form, rather than in detail, to avoid obscuring the present disclosure. Reference throughout this specification to “an implementation” or “one implementation” “at least one implementation,” or “some implementations” means that a particular feature, structure, function, or characteristic described in connection with the implementation is included in at least one implementation of the disclosure. The appearances of the phrase “in an implementation,” “in at least one implementation,” “in one implementation,” or “some implementations” in various places throughout this specification are not necessarily referring to the same implementation of the disclosure. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.
Here, terms “coupled” and “connected,” along with their derivatives, may be used to describe functional or structural relationships between components. These terms are not intended as synonyms for each other. Rather, in at least one implementation, “connected” may be used to indicate that two or more elements are in direct physical, optical, or electrical contact with each other. Here, “coupled” may be used to indicate that two or more elements are in either direct or indirect (with other intervening elements between them) physical, electrical or in magnetic contact with each other, and/or that the two or more elements co-operate or interact with each other (e.g., as in a cause an effect relationship). Here, “coupled” may also generally refer to direct attachment of one electronic component to another. An electric or magnetic field may couple one component to another, where the field is controlled by one component to influence the other in some manner.
Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by “at least one of” or “one or more of” can mean any combination of the listed terms.
Here, “substantially,” “close,” “approximately,” “near,” and “about,” generally refer to being within +/−10% of a target value. For example, unless otherwise specified in explicit context of their use, terms “substantially equal,” “about equal” and “approximately equal” mean that there is no more than incidental variation between among things so described. In at least one implementation, such variation is typically no more than +/−10% of a predetermined target value.
Here, “wafer” may generally refer to a substrate comprising a semiconductor material. For example, a wafer may be disc-shaped. In at least one implementation, a wafer diameter may range between 100 mm and 450 mm.
Here, “plasma enhanced chemical vapor deposition (PECVD)” may generally refer to a method of thin film deposition whereby a chemical vapor comprising film precursor molecules may undergo surface reactions, forming nucleation and a polymerized or otherwise condensed film on a wafer. In at least one implementation, a plasma is formed within a PECVD deposition chamber by injection of electromagnetic fields into precursor vapors to increase the chemical reactivity of the precursor species.
Here, “process module” may generally refer to a high vacuum chamber (e.g., operable to hold a pressure of 20 torr or less), component of a semiconductor fabrication tool. In at least one implementation, process module may generally house the tools such as a showerhead assembly and a wafer pedestal for performing a semiconductor fabrication processes on a substrate. In at least one implementation, substrate may be a semiconductor wafer, for example, held within the process module. In at least one implementation, process performed on the substrate may be a thin film deposition performed as a physical deposition process such as a metal film evaporation process, a sputtering process, etc. In at least one implementation, other thin film fabrication processes include chemical vapor deposition (CVD) processes, atomic layer deposition (ALD) processes, PECVD deposition processes, etch processes, such as a reactive ion etch (RIE), or plasma cleaning processes. In at least one implementation, a process module may comprise at least one wafer processing station into which the substrate is transferred for processing.
Here, “pedestal” may generally refer to a column on which a wafer chuck (chuck) may be supported. In at least one implementation, wafer may be mounted and clamped on the chuck for processing within a process module. In at least one implementation, a pedestal may include a motor operable to raise and lower the height of the chuck.
Here, “wafer chuck” may generally refer to a platform on which a wafer or other substrate may be mounted and clamped. In at least one implementation, a wafer chuck may be supported on a pedestal. In at least one implementation, chuck may be operable to electrostatically clamp a wafer or other substrate for processing within a process module, for example. “Wafer chuck” may be used interchangeably with “chuck”.
Here, “viewport window” may generally refer to a transparent window within a wall of a process module to allow viewing within the process module. In at least one implementation, a viewport window may comprise sapphire, glass, quartz, or fused silica.
Here, “wall” may generally refer to an outer partition or surface of an enclosure for a chamber such as a process module. In at least one implementation, a wall may be a planar portion of an enclosure, joined to edges of other similar walls at angles such as orthogonal angles.
Here, “spatial sensor” may generally refer to a vision sensor such as a video camera. In at least one implementation, a spatial sensor may comprise an optical transducing element.
Here, “optical axis” may generally refer to a lens axis of a spatial sensor. The optical axis is a reference that may be used for determining the orientation of a spatial sensor.
Here, “optical transducing element” may generally refer to a system of optical elements, including lenses and at least one charge capture device (CCD) array to transduce light patterns into electronic voltages.
Here, “field of view” may generally refer to a region of space that is captured optically by an optical transducing element. In at least one implementation, a view cone of an optical transducing element may encompass a field of view.
Here, “robot arm” may generally refer to a mechanical device comprising two or more articulated beams or elongated structures that may be actuated by servo mechanisms or electric motors. In at least one implementation, a robot arm may comprise an end effector attached to an extremity of the robot arm.
Here, “end effector” may generally refer to a wafer handling device attached to the end of a robot arm. In at least one implementation, an end effector is a wafer paddle. In at least one implementation, an end effector comprises a turntable. In at least one implementation, an end effector comprises alignment pins or other structures.
Here, “vacuum transfer module” may generally refer to a chamber adjacent to a process module. A wall of may divide the vacuum transfer module from the process module. A slit valve may provide communication between the process module and the vacuum transfer module. A vacuum module in which a robot arm may be housed. In at least one implementation, a wafer may be transferred into a vacuum transfer module and handed off to a robot arm that is housed within the vacuum transfer module. The robot arm within the vacuum transfer module may transfer the wafer into the process module.
Here, “slit valve” may generally refer to a slot within a wall of a process module that comprises a door or hatch that may be actuated by a motor to open or shut the slit valve. In at least one implementation, a slit valve may enable passage of wafers through a wall of a process module.
Here, “gimbal mechanism” may generally refer to a ball and socket joint that is rotatable in all directions. An elongated member may extend from the ball joint to attach a device or object that may be pivoted or rotated by the gimbal mechanism.
Here, “gantry rail” may generally refer to a rail or system of rails that support a device or object, along which the device or object may slide in order to move the device or object laterally. In at least one implementation, a gantry rail may include a movable track or pulley system to enable motorized actuation of the gantry system, of which a gantry rail is part.
Here, “enclosure” may generally refer to a housing enclosing a device or object. In at least one implementation, an enclosure may be employed to house a spatial sensor within a process module to protect the spatial sensor from the environment within the process module.
Here, “environment” may generally refer to conditions within a process module. For example, in at least one implementation, a plasma may be present within the process module, which may potentially damage sensitive devices such as a spatial sensor. Other conditions, such as vacuum and high temperature (e.g., by radiative heat transfer), may be equally damaging. An enclosure may provide sufficient protection for the device.
Here, “computing device” may generally refer to an electronic system comprising a processor and a memory coupled to the processor. In at least one implementation, a computing device may be a dedicated computational circuit comprising a microprocessor or a general-purpose computer.
Here, “processor” may generally refer to an electronic device comprising a plurality of digital logic circuitry operable to execute binary instructions or machine-readable code read from a memory.
Here, “memory” may generally refer to an array of electronic on-off switches, such as field effect transistors controllable by digital voltages applied to a gate of the field effect transistor, operable to store binary data in the form of processor-readable digital voltages. In at least one implementation, a memory may be any suitable storage medium, such as a volatile or non-volatile read-only memory or a random-access memory.
Here, “machine-readable binary code” may generally refer to a set of binary instructions embodied by software. “Machine” may refer to a processor operable to read and execute the binary code.
Here, “machine learning algorithm” may generally refer to a software algorithm operable to learn from data. In at least one implementation, data may be obtained by training operations conducted by a human operator or by another software program, for example.
Here, “machine vision algorithm” may generally refer to a software algorithm operable to recognize shapes, measure distances, determine size of objects contained within image data, etc. In at least one implementation, machine vision algorithms are operable to process raw video stream data or still images into image data suitable for image analysis by software. Machine vision software algorithms may convert images to binary streams, where the algorithm may map the binary data into memory blocks and look for shapes or colors that it is taught to identify.
Here, “algorithm” may generally refer to a collection of computer code that performs a task. The algorithm may comprise a series of mathematical operations.
Here, “transduced optical data” may generally refer to a raw video electronic data obtained by transducing optical signals (e.g., light) into electronic voltages. The electronic voltages may be digitized into binary numbers representing light levels and/or color.
Here, “video data stream” may generally refer to video data sent between a spatial sensor to a computing device as a stream of data packets. In at least one implementation, a video data stream comprises image frames. In at least one implementation, the video data stream may be managed by any suitable streaming software.
Here, “frame” may generally refer to a block of video data, where the block comprises a specified number of data bytes.
Here, “threshold” may generally refer to a number limit above which a change in an operation or process occurs. For example, particle size exceeding a particle size threshold may trigger a clean operation of a process module.
Here, “clean operation” may generally refer to an operation of a process module where material deposited on non-target surfaces within the process module are cleaned by a series of cleaning procedure steps. The clean may include a bake step and may also include opening the process module by a user or technician to manually clean the inside.
Here, “positional data” may generally refer to data comprising x, y and z coordinates of an end effector or other device, in accordance with at least one implementation. In at least one implementation positional data may be referenced to reference x, y and/or z coordinates designated for the process system.
Here, “process system” may generally refer to a process tool comprising a process module, a wafer transfer module, a load lock, etc. In at least one implementation, a process system may further comprise an array of spatial sensors, a computing device electronically coupled to the spatial sensors and other devices within the process system.
Here, “teach fixture” may generally refer to a ring structure having alignment structures or reference marks for aligning a robot arm or end effector for placement of a wafer on a chuck. In at least one implementation, a teach fixture may be employed to obtain and store coordinates of an end effector for placement of a wafer onto a chuck.
Here, “calibration ring” may generally refer to a ring structure having alignment structures or marks for aligning a robot arm or end effector on a chuck. In at least one implementation, a calibration ring may be employed to teach machine learning software to center a wafer on a chuck.
Here, “reference markers” may generally refer to marks or structures on a device such as a teach fixture or calibration ring for alignment of an end effector during a wafer handoff operation.
Here, “pinning hole” may generally refer to an alignment hole within a teach fixture and an end effector. In at least one implementation, an end effector may be aligned on a teach fixture, whereby an alignment pin is inserted through the pinning holes to fix the coordinates of the end effector for proper positioning of the end effector for wafer transfer to a chuck.
Here, “wafer handoff” may generally refer to an operation comprising transfer of a wafer from one end effector to another end effector, or from an end effector to a chuck.
Here, “wafer handoff z-coordinate” may generally refer to a vertical coordinate or z-height of an end effector that is determined by machine learning software for a wafer handoff operation.
Here, “acentric offset” may generally refer to an eccentricity in placement of a wafer on a chuck. A centering tolerance may be stated, where a wafer may be positioned approximately at the center of the chuck but have a slight offset with components in the x and/or y directions. For example, if the tolerance is +/−50 microns, an acentric offset may be a difference between the absolute coordinates of the center of the wafer and the 50-micron limit. If the y component of the wafer center with respect to the chuck center (or to a reference contour that is centered on chuck center) is 100 microns, for example, then the acentric offset is +50 microns in the y direction.
Here, “reference contour” may generally refer to a centering reference, such as a mark on the chuck, an inner sidewall of an edge ring, a teach fixture or a calibration ring. The rings are assumed centered on the chuck center. A reference contour may be useful for measurement of the distance between a wafer edge and the reference contour to determine an acentric offset.
Here, “showerhead” may generally refer to a process gas distribution manifold. In at least one implementation, a showerhead assembly comprises a faceplate that comprises a plurality of orifices from which process gases issue into the process module. In at least one implementation, a showerhead assembly may be a component of a wafer processing station. In at least one implementation, a showerhead assembly may be employed to distribute process gasses into processing chambers for atomic layer deposition processes (ALD), plasma—enhanced atomic layer deposition (PEALD), chemical vapor deposition (CVD) processes, plasma-enhanced thin film deposition (e.g., PECVD), as well as for plasma etching (e.g., RIE) and plasma cleaning processes. Here, “showerhead” may be used interchangeably with the term “showerhead assembly”.
Here, “film” may generally refer to a thin layer of solid material on a substrate, such as a wafer. In at least one implementation, a film may be intentionally deposited or grown by number of processes, such as atomic layer deposition, plasma-enhanced atomic layer deposition, chemical vapor deposition and plasma-enhanced chemical vapor deposition.
Here, “wafer” may generally refer to a semiconductor or insulative disc-shaped substrate. In at least one implementation, a wafer may be processed for microelectronic or microelectromechanical systems device manufacture. For example, films may be grown on a wafer by chemical vapor deposition methods or by plasma-enhanced chemical vapor deposition methods.
Here, “surface roughness” may generally refer to a measurable deviation of film surface topography from a flat reference thickness. Surface roughness may be reported as an average roughness or a root-mean-square (rms) roughness. Surface roughness may be measured by metrology instruments known in the art. In at least one implementation, surface roughness may be measured by imaging a surface and subsequent analysis by image processing software.

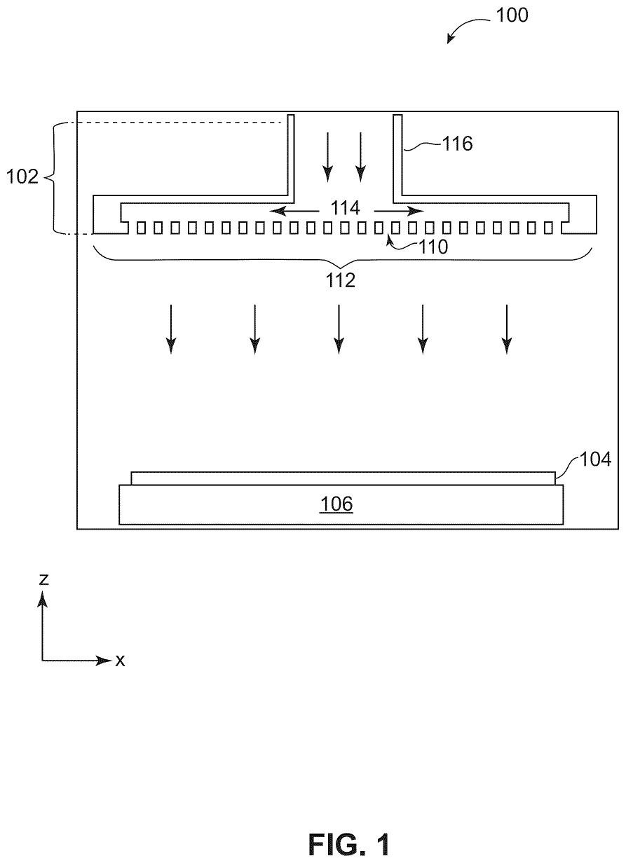

FIG. 1 illustrates a cross-sectional view of process module 100, in accordance with at least one implementation. In at least one implementation, in the cross-sectional view, process module may be oriented such that the z-axis is aligned along the vertical. It is to be understood by persons skilled in the art that references to “above” and “below” have the normal meanings, as noted herein. In at least one implementation, “above” and “below” refer to relative vertical positions of a first object and a second object above a reference plane. In at least one implementation, a reference plane may be a floor of a room in which the objects are located. Process module 100 may be normally oriented as shown in FIG. 1, in accordance with at least one implementation.

In at least one implementation, process module 100 comprises a vacuum chamber in which thin film and other processes may be performed on a substrate. In at least one implementation, process module 100 may be a component of a semiconductor integrated circuit fabrication tool. In at least one implementation, process module 100 may be a deposition chamber, in which deposition processes such as chemical vapor deposition (CVD), atomic layer deposition (ALD), plasma-enhanced atomic layer deposition (PEALD), plasma-enhanced chemical vapor deposition (PECVD), physical deposition processes such as evaporation, sputtering and the like may be performed. In at least one implementation, process module 100 may also be employed for dry etching processes, such as reactive ion etching (RIE) or plasma cleaning processes.

In at least one implementation, depositions such as PECVD may be performed under moderate to high vacuum (e.g., less than 20 torr). In at least one implementation, process module 100 comprises a PECVD chamber. In at least one implementation, process module 100 comprises gas distribution showerhead 102 (hereinafter, showerhead 102) located directed above wafer 104. In at least one implementation, wafer 104 has a circular disk form factor, which, for example, may have a diameter ranging between 100 mm and 450 mm. In at least one implementation, wafer 104 comprises a semiconductor material, such as silicon, germanium, gallium arsenide, indium phosphide, cadmium telluride, and the like. In at least one implementation, wafer 104 comprises a dielectric material such as silicon nitride, silicon carbide, silicon oxide (e.g., fused silica, borosilicate glass, float glass), aluminum nitride, aluminum oxide, and the like. While the method disclosed herein is directed to semiconductor device fabrication, such as silicon-based integrated circuits, in at least one implementation, method may also be readily applied to fabrication of other types of devices. In at least one implementation, wafer 104 may be a liquid crystal display panel substrate. In at least one implementation, a substrate may have a rectangular form factor. In at least one implementation, showerhead 102 may have a rectangular form factor of approximately the same dimensions as the rectangular substrate.

In at least one implementation, wafer 104 is mounted on chuck 106. Showerhead 102 comprises faceplate 112 facing wafer 104. Faceplate 112 may comprise a plurality of orifices 110 opening to plenum 114. In at least one implementation, process gases may flow into conduit 116 from an external gas source. In at least one implementation, conduit 116 opens into plenum 114.

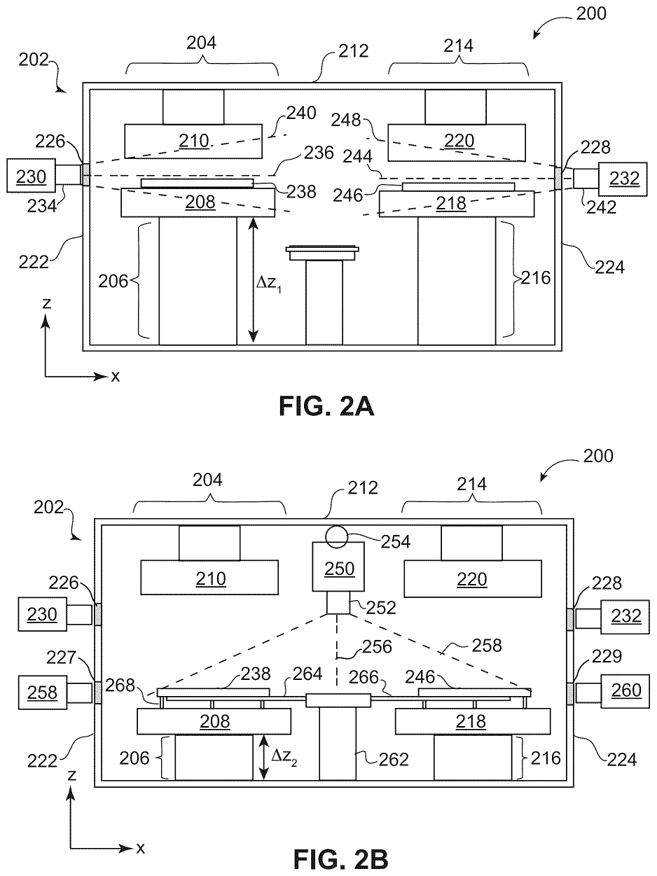

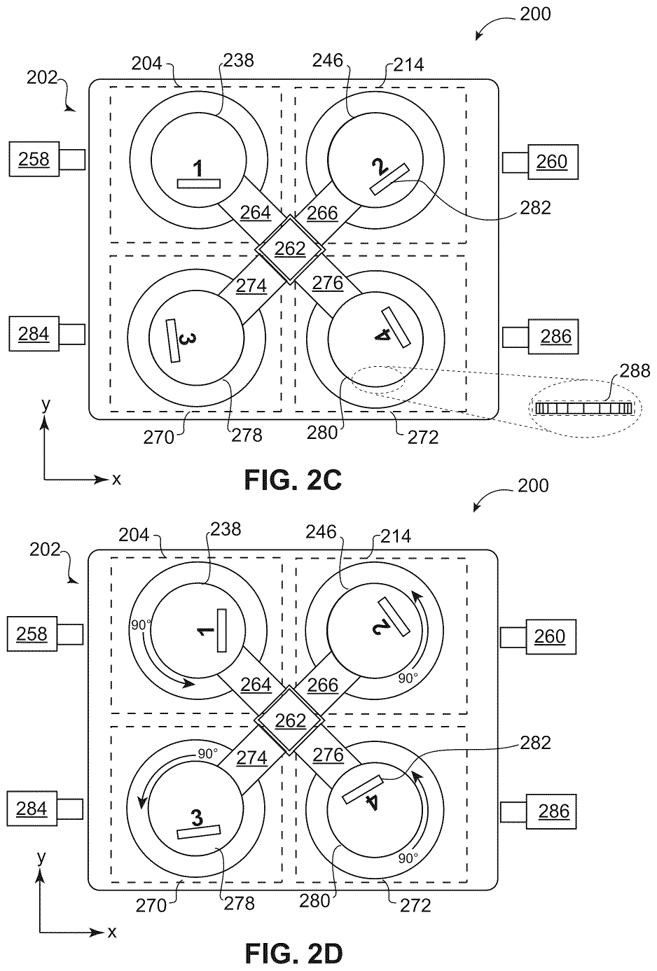

FIG. 2A illustrates a profile view of process system 200, in accordance with at least one implementation. In at least one implementation, process system 200 comprises process module 202. In at least one implementation, process module 202 comprises a vacuum chamber operable to maintain a high vacuum. In at least one implementation, process module 202 comprises multiple process stations. In at least one implementation, process module 202 may be a dual or quad station module, comprising two or four process stations, respectively. In FIG. 2A, two process stations are shown, in accordance with at least one implementation. In at least one implementation, process station 204 may comprise pedestal 206, wafer chuck 208 (hereinafter chuck 208) on top of pedestal 206, and showerhead 210 over chuck 208. In at least one implementation, showerhead 210 may be coupled to gas delivery lines extending through top wall 212. In at least one implementation, process station 214 station may be adjacent to process station 204. Process station 214 may comprise pedestal 216, chuck 218 on top of pedestal 216, and showerhead 220 over chuck 218. In at least one implementation, spindle 262, described below, is situated between process stations 204 and 214. In at least one implementation, chucks 208 and 218, as well as all references to chucks below, may employ electrostatic clamping (ESC) for securing a wafer.

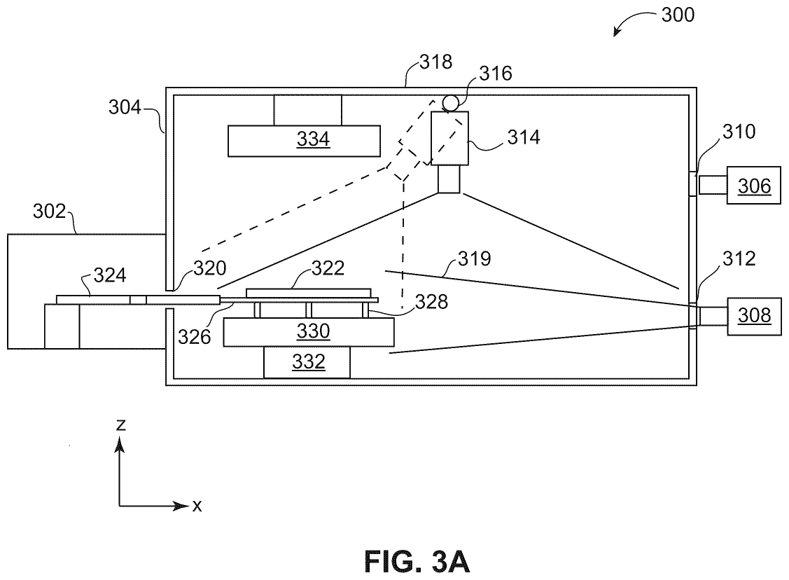

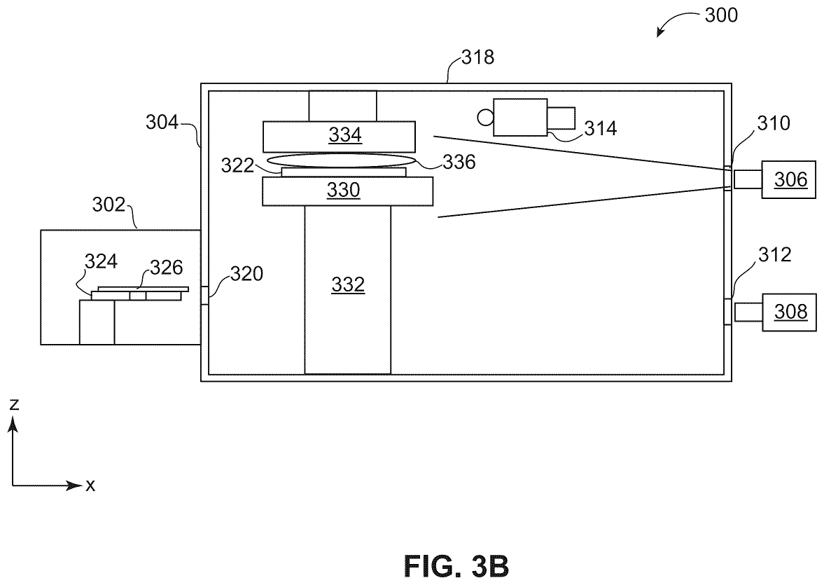

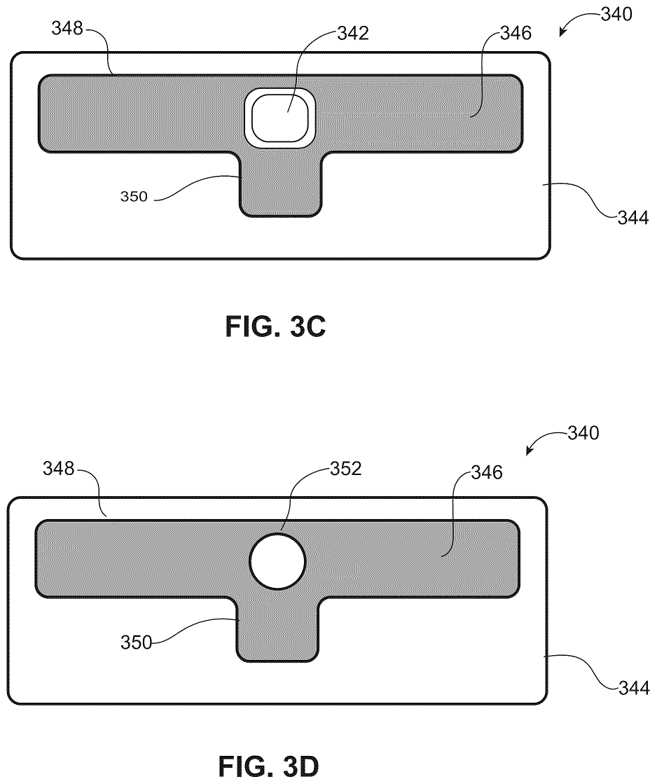

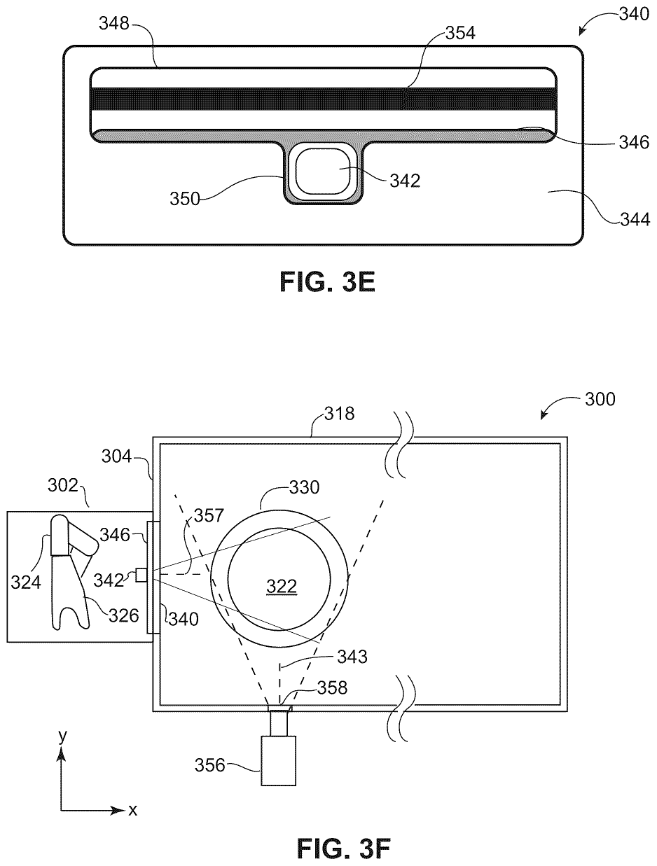

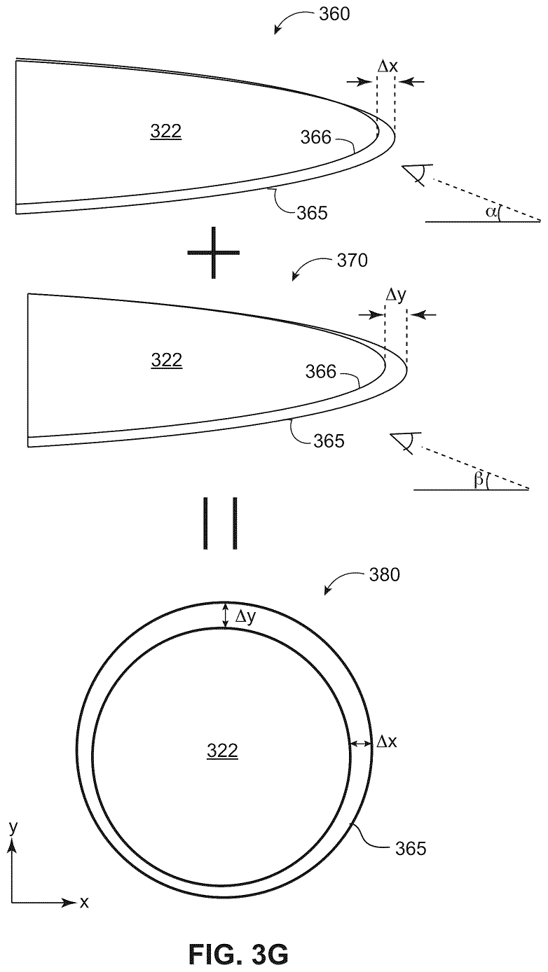

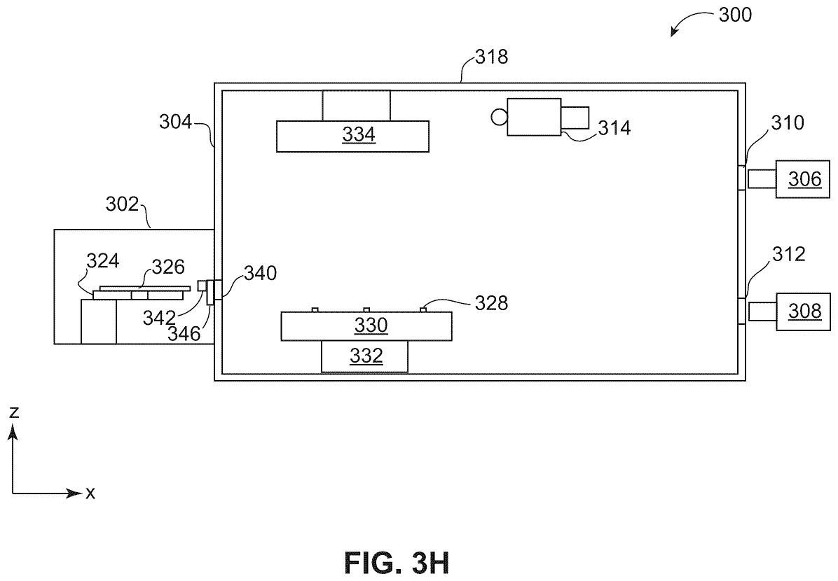

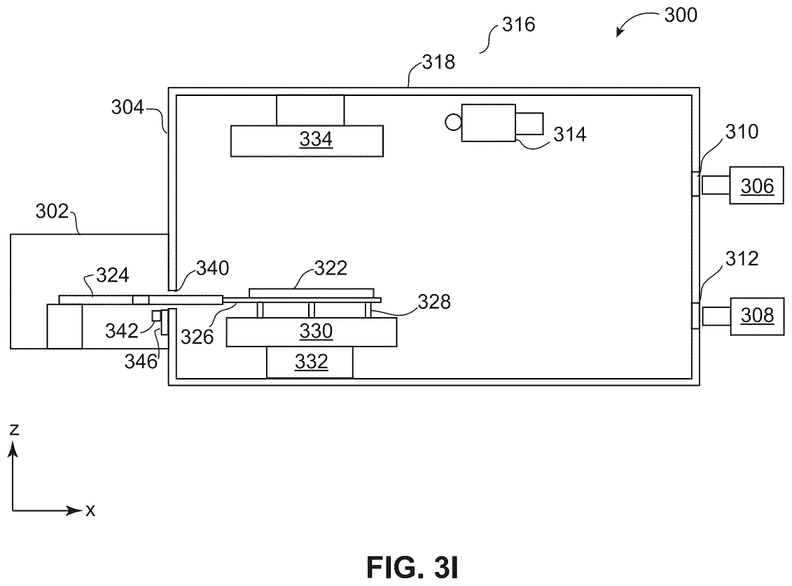

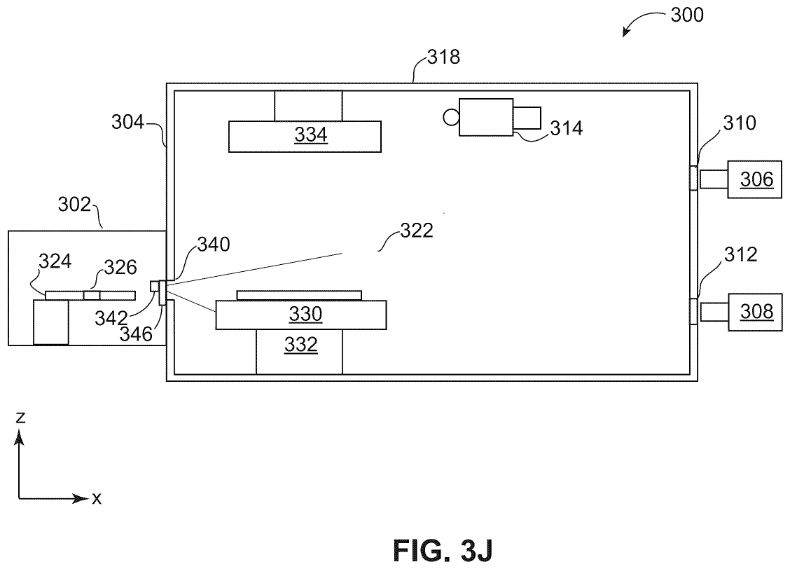

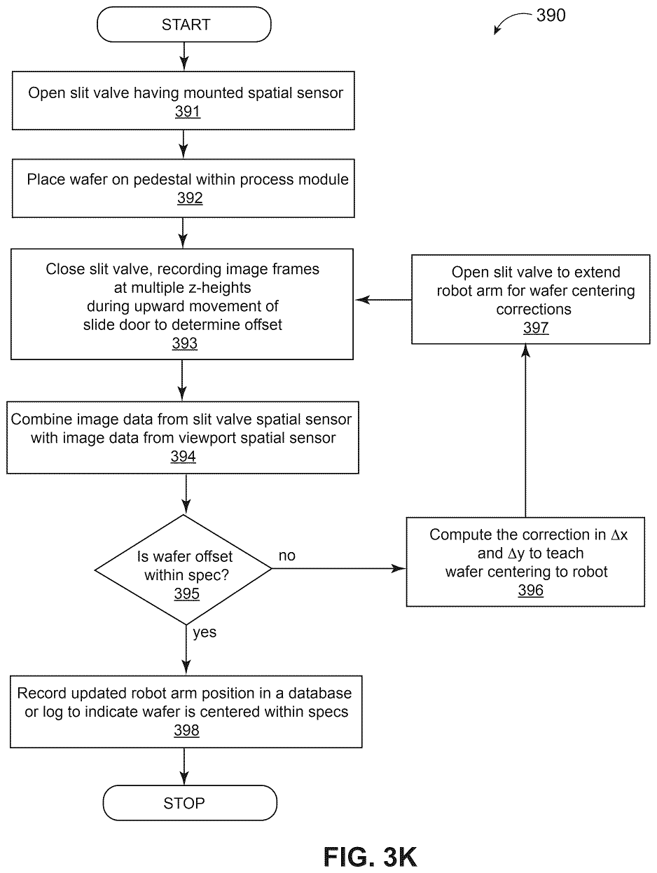

In at least one implementation, process module 202 comprises wall 222 and wall 224. In at least one implementation, walls 222 and 224 comprise viewport window 226 and viewport window 228, respectively. In at least one implementation, a wafer transfer module, (see FIGS. 3A and 3B) may be adjacent to process module 202 and share a common wall orthogonal to walls 222 and 224 on process module 202. In at least one implementation, a robot arm (described below; see FIGS. 3A and 3B) may be operable to transfer wafers from the wafer transfer module to pedestals 206 and 216 within process module 202.

In at least one implementation, viewport windows 226 and 228 comprise sapphire, fused silica, quartz or borosilicate glass. In at least one implementation, spatial sensor 230 may be adjacent to viewport window 226 and spatial sensor 232 may be adjacent to viewport window 228. In at least one implementation, spatial sensor 230 comprises optical transducing element 234. In at least one implementation, spatial sensors 230 and 232 are cameras that are operable to capture still and/or motion images.

In at least one implementation, optical transducing element 234 comprises camera optics, including an optical lens and a charge coupled device (CCD) array. In at least one implementation, CCD array is sensitive to the visible light spectrum (e.g., from approximately 700 nm to 400 nm) for conversion of optical light patterns into an array of electronic voltages. In at least one implementation, optical transducing element 234 comprises optical axis 236. In at least one implementation, optical transducing element 234 may have a visual view through viewport window 226. In at least one implementation, optical transducing element 234 may be operable to capture light emanating from within process module 202 or reflected from objects inside of process station 204 within process module 202, such that spatial sensor 230 has a visual view through viewport window 226 into the interior of process module 202. In at least one implementation, spatial sensor 230 comprises a light source (not shown). In at least one implementation, light source may provide illumination to facilitate visualization of the interior of process module 202 by spatial sensor 230. In at least one implementation, spatial sensor 230 may have an edge-on view of wafer 238 and chuck 208.

In at least one implementation, optical transducing element 234 may be aimed at wafer 238 mounted on chuck 208, where wafer 238, chuck 208 and showerhead 210 may be within the field of view within view cone 240 of spatial sensor 230. In at least one implementation, optical transducing element 234 may incorporate a narrow-angle lens having view cone 240. In at least one implementation, chuck 208 may be raised and lowered by pedestal 206, bringing wafer 238 and chuck 208 into view and out of view of spatial sensor 230. In FIG. 2A, pedestal 206 is shown to be extended to a z-height Δz₁, in accordance with at least one implementation.

In at least one implementation, spatial sensor 232 comprises optical transducing element 242. In at least one implementation, optical transducing element 242 comprises camera optics, including an optical lens and a charge coupled device (CCD) array. In at least one implementation, CCD array may be sensitive to visible light spectrum (e.g., from approximately 700 nm to 400 nm) for conversion of optical light patterns into an array of electronic voltages. In at least one implementation, optical transducing element 242 comprises optical axis 244. In at least one implementation, optical transducing element 242 may have a view through viewport window 228. In at least one implementation, optical transducing element 242 may be operable to capture light emanating from within process module 202 or reflected from objects inside of process station 214 of process module 202. In at least one implementation, spatial sensor 232 has a visual view through viewport window 228 into the interior of process module 202.

In at least one implementation, spatial sensor 232 may comprise a light source (not shown). In at least one implementation, a light source may be provided separately. In at least one implementation, a light source may provide illumination to facilitate visualization of the interior of process module 202 by spatial sensors 230 and 232. For example, wafer 246, chuck 218 and showerhead 220 may be within view cone 248 of spatial sensor 232. In at least one implementation, spatial sensor 232 may have an edge-on view of wafer 246 and chuck 218.

In at least one implementation, spatial sensors 230 and 232 may be electronically coupled to a computing device (not shown here), such as control module or other device comprising a dedicated microprocessor, or a general-use computer In at least one implementation, the computing device may comprise a processor and a memory electronically coupled to the processor for storing machine vision and/or machine learning software. In at least one implementation, spatial sensors 230 and 232 may provide data streams containing video data to the computing device. In at least one implementation, video data may be captured and analyzed by machine vision software, and stored in data buffers within the memory.

In at least one implementation, measurements of spatial coordinates (e.g., x, y, and z) of wafers 238 and 246 on chucks 208 and 218, respectively, as well as vertical (e.g., z-height) coordinates of chucks 208 and 218 may be performed by machine vision software. In at least one implementation, spatial sensors 230 and 232 may capture movement of wafers 238 and 246 while being transferred (described below), or vertical movement of chucks 208 and 218 when actuated by pedestals 206 and 216, respectively. In at least one implementation, machine vision software may visually measure horizontal and vertical distances traversed by wafers 238 and 246 and store these data. In at least one implementation, measurement data from machine vision software may be shared with machine learning software. In at least one implementation, machine learning software may be trained by algorithms contained within system software to capture positional data of wafers 238 and 246 during wafer transfer operations. In at least one implementation, coordinates of chucks 208 and 218 may be recalled in future operations.

In at least one implementation, unsupervised training is applied to train a model used for machine learning. In at least one implementation, training a model may involve applying measurement data. In at least one implementation, training sets may initially be human generated. In at least one implementation, spatial sensors (e.g., cameras) may provide data that may feed image processing algorithms that are capable of measuring distances. In at least one implementation, machine learning software may determine how far to move a robot arm, and in which direction to move it. In at least one implementation, machine learning software may determine when a wafer is centered over a chuck, and when to lift pins, and when to lower pins, etc.

In at least one implementation, spatial sensors 230 and 232 may monitor edges of wafers 238 and 246, respectively, for buildup of particulates during deposition processes. In at least one implementation, software (e.g., machine-learning software) may be provided to sort and measure particle size and position of particles on wafers 238 and 246. In at least one implementation, software may be operable to trigger a notification for a clean operation.

In at least one implementation, machine-learning software may be trained with the aid of spatial sensors 230 and 232 to autonomously perform complex movements of robot arms, wafer indexing mechanisms and pedestal movements for wafer transfer operations. In at least one implementation, spatial sensors 230 and 232 capture images that are converted into data, and that data is used to train a machine learning model. In at least one implementation, the data collected by spatial sensors 230 and 232 include or are used to calculate horizontal and vertical distances traversed by wafers during different wafer transfer operations. In at least one implementation, autonomous wafer positioning operations may replace manual and semiautomatic wafer positioning operations, providing significant time savings and mitigation of down time of process system 200. In at least one implementation, machine learning software employs unsupervised training algorithms.

FIG. 2B illustrates a profile view of process system 200, comprising at least one spatial sensor 250 for overhead viewing, in accordance with at least one implementation. In at least one implementation, spatial sensor 250 may be located within interior of process module 202. In at least one implementation, spatial sensor 250 may be attached to top wall 212 between process stations 204 and 214. In at least one implementation, spatial sensor 250 comprises optical transducer element 252. In at least one implementation, spatial sensor 250 comprises gimbal mounting mechanism 254 attached to top wall 212. In at least one implementation, spatial sensor 250 may be operable to swivel in all directions over a range of angles to point optical axis 256 at angles ranging between zero and 90 degrees with respect to the plane of top wall 212. In at least one implementation, spatial sensor 250 may be mounted on a gantry rail system (not shown). In at least one implementation, spatial sensor 250 may be operable to translate on the gantry rail system (for example, in the x and y directions) within process module 202 to obtain overhead and/or oblique views of process stations 204 and 214.

In at least one implementation, spatial sensor 250 may be a permanent fixture within process module 202. In at least one implementation, spatial sensor 250 may be temporary fixture within process module 202. In at least one implementation, spatial sensor 250 may be removable. In at least one implementation, spatial sensor 250 may be employed when process module 202 is being serviced. In at least one implementation, process module 202 may be opened, allowing an overhead view from spatial sensor 250 from an exterior vantage point. In at least one implementation, spatial sensor 250 may be mounted on an external support to obtain an overhead view within process module 202. In at least one implementation, spatial sensor 250 may be housed in a protective enclosure (not shown), if employed as a permanent feature of process system 200. In at least one implementation, an enclosure may prevent exposure of spatial sensor 250 to a potentially harsh environment within process module 202.

In at least one implementation, temporary employment of spatial sensor 250 may enable overhead and/or oblique views of chucks 208 and 218 and/or wafers 238 and 246 during part replacement or realignment without committing space within process module 202 for a permanent interior installation. In at least one implementation, temporary employment of spatial sensor 250 may enable teaching new robot arm movements and end effector positions to system software without committing space and other resources within process module 202.

In at least one implementation, spatial sensor 250 may be electronically coupled to a computing device (not shown) in both temporary and permanent installations. In at least one implementation, spatial sensor 250 may be employed with spatial sensors 230 and 232. In at least one implementation, spatial sensor 250 may provide overhead views looking down on chucks 208 and 218. In at least one implementation, image data from these overhead views may be combined with side views taken by spatial sensors 230 and 232.

In FIG. 2B, spatial sensor 250 is shown to have a wide-angle overhead view to observe both wafers 238 and 246 parked in process stations 204 and 214, in accordance with at least one implementation. In at least one implementation, process module is a quad station module, comprising four process stations. In at least one implementation, process stations 204 and 214 may be two of four stations in a quad station module. In at least one implementation, optical transducer element 252 comprises a wide-angle lens to capture wide-angle field of view images, such as within view cone 248. In at least one implementation, view cone 248 may extend over four process stations, including process stations 204 and 214.

In FIG. 2B, pedestals 206 and 216 are shown in a lowered position, where the z-heights of chucks 208 and 218 have been reduced relative to the z-heights shown in FIG. 2A, in accordance with at least one implementation. In at least one implementation, z-heights (Δz₂) of pedestals 206 and 216 may be referred to a fixed reference position within process module 202. In at least one implementation, pedestals 206 and 216 may be at a home position. In at least one implementation, home position is aligned with slit valves (not shown) within walls 222 and 224 of process module 202.

In at least one implementation, robot arms within vacuum transfer modules (not shown) are aligned with slit valves (not shown) aligned to home position of pedestals 206 and 216 to transfer wafers (e.g., wafers 238 and 246) into and out of process module 202. In at least one implementation, spatial sensors 258 and 260 may be included within process system 200 to view chucks 208 and 218, respectively, and to monitor wafer transfer operations from side views when pedestals 206 and 216 are at the home position.

In at least one implementation, spatial sensors 258 and 260 may be located on the exterior of process module 202. In at least one implementation, spatial sensors 258 and 260 may view chucks 208 and 218 through viewport windows 227 and 229, aligned to the home position of pedestals 206 and 216. In at least one implementation, spatial sensors 258 and 260 may include narrow-angle lenses to view chucks 208 and 218, respectively, as well as wafers 238 and 246, respectively.

In at least one implementation, wafers 238 and 246 may be viewed edge-on by spatial sensors 258 and 260. In at least one implementation, spatial sensors 258 and 260 may monitor wafer vertical distances in wafer transfer operations to and from chucks 208 and 218. In at least one implementation, spatial sensors 258 and 260 may be employed simultaneously with spatial sensor 250 to monitor operations, including wafer transfer and wafer centering operations on chucks 208 and 218.

In at least one implementation, process module 202 comprises spindle 262. In at least one implementation, arms 264 and 266 are attached to top of spindle 262. In at least one implementation, arms 264 and 266 may include wafer paddles or other structures for holding wafers 238 and 246. In at least one implementation, arms 264 and 266 may lift wafers 238 and 246 from lift pins 268 extending from chucks 208 and 218. In at least one implementation, arms 264 and 266 are two of four similar arms extending from spindle 262. In at least one implementation, spindle 262 may be operable to rotate arms 264 and 266, for example to transfer wafers 238 and 246 between process stations (e.g., an indexing operation to change wafer index between process stations 204 and 214). In at least one implementation, arms 264 and 266 may comprise turntables or other end effectors located at the ends of arms 264 and 266 to rotate or spin wafers 238 and 246 while held by arms 264 and 266. In at least one implementation, spatial sensor 250 may be positioned overhead to measure angular motion (e.g., spindex) of wafers 238 and 246 while being rotated.

FIG. 2C illustrates a plan view of process system 200 during an automated machine learning event, whereby spindle rotation training sets are obtained for spindle calibration or re-calibration in accordance with at least one implementation. In at least one implementation, process system 200 comprises process module 202, comprising process stations 204, 214, 270, and 272. Process stations 204, 214, 270, and 272 are shown from overhead. Dashed boxes delineate process stations 204, 214, 270, and 272. In at least one implementation, spatial sensor 250 (not shown here) may be employed to observe process stations 204, 214, 270, and 272 from in an overhead vantage point. In at least one implementation, spindle 262 comprises arms 264, 266, 274, and 276. In at least one implementation, arms 264, 266, 274, and 276 carry wafers 238, 246, 278, and 280, respectively. In at least one implementation, wafers 238, 246, 278, and 280 are calibration wafers carrying markings such as angle measurement markers 282. In at least one implementation, angle measurement markers 282 may be oriented randomly, as shown.

In at least one implementation, process system 200 may include spatial sensors 258, 260, 284, and 286. In at least one implementation, spatial sensors 258, 260, 284, and 286 are positioned at viewport windows (not shown) at each process station 204, 204, 270, and 272, respectively. In at least one implementation, spatial sensors 258, 260, 284, and 286 may be employed in addition to an overhead spatial sensor, such as spatial sensor 250. In at least one implementation, spatial sensors 258, 260, 284, and 286 have an edge-on view of wafers 238, 246, 278, and 280, respectively.

In at least one implementation, wafers 238, 246, 278, and 280 may have edge markings 288, as shown in the inset. In at least one implementation, edge markings 288 may be recorded by spatial sensors 258, 260, 284, and 286 to mark angles of rotation of wafers 238, 246, 278, and 280, respectively. In at least one implementation, rotational angles may be determined by counting numbers of bars of edge markings 288 passing through the view field, for example. In at least one implementation, the rotational angle determination by positional counting edge markings may be performed by machine vision and/or machine learning modules contained within system software.

FIG. 2D illustrates a plan view of process system 200 during an automated machine-learning event, according to at least one implementation. A machine learning event may bean operation during which training data are collected. An example operation is a spindle calibration or re-calibration for wafer transfer operations, according to at least one implementation. In at least one implementation, wafers 238, 246, 278 and 280 are rotated 90 degrees counterclockwise. In at least one implementation, spatial sensor 250, overhead, may capture the positions of angle measurement markers 282 after rotation to visually mark a 90-degree counterclockwise rotation of wafers 238, 246, 278, and 280. In at least one implementation, video data recorded during the machine-learning event may be buffered in a memory coupled to a computing device (not shown) that may be electronically coupled to spatial sensor 250. In at least one implementation, machine-learning software may be taught to quantify angular rotations of the sort illustrated in FIG. 2D for production wafers during processing.

In at least one implementation, spatial sensors 258, 260, 284, and 286 may capture angular rotation data by capturing movement of edge markings 288. In at least one implementation, spatial sensors 258, 260, 284, and 286 may capture edge-on images from side views, while spatial sensor 250 may capture overhead images. In at least one implementation, both side and overhead images may be stored in data buffers in a memory electronically coupled to the computing device (not shown). In at least one implementation, machine vision software may share the image data with machine learning software by accessing a memory data block, for example. In at least one implementation, machine learning software accesses one or more video frames from a memory location in a memory data block. These video frames may indicate the position of a robot arm, for example. In at least one implementation, machine learning software learns the movement of the robot arm and uses this learning to re-calibrate the robot arm.

FIG. 3A illustrates a profile view of process system 300, comprising vacuum transfer module 302 and process module 304, in accordance with at least one implementation. In at least one implementation, vacuum transfer module 302 and process module 304 share a wall in common. In at least one implementation, process system 300 comprises spatial sensors 306 and 308 on exterior of process module 304. In at least one implementation, spatial sensors 306 and 308 are operable to view into process module 304 through viewport windows 310 and 312. In at least one implementation, spatial sensor 314 may be mounted in an overhead position. In at least one implementation, spatial sensor 314 has a wide-angle view cone, as shown. In at least one implementation, spatial sensor 314 may be operable to pivot by gimbal mechanism 316. In at least one implementation, gimbal mechanism 316 may be operable to pivot between zero and 90 degrees in a vertical angle, and 360 degrees azimuthally, with respect to the plane of top wall 318.

In at least one implementation, spatial sensor 308 may have a view of a lower portion of process module 304 relative to spatial sensor 306, which may have a view of an upper portion of process module 304. In at least one implementation, spatial sensor 308 may be operable to capture video data of a wafer transfer operation. In at least one implementation, view cone 319 of spatial sensor 308 may be trained on a region of process module 304 encompassing slit valve 320. In at least one implementation, slit valve 320, mounted on the common wall between vacuum transfer module 302 and process module 304, may be an entry port into process module 304. In at least one implementation, wafer 322 may be transferred from vacuum transfer module 302 into process module 304 through open slit valve 320. In at least one implementation, wafer 322 may be transferred from vacuum transfer module 302 into process module 304 by robot arm 324 and carried on end effector 326. In at least one implementation, robot arm 324 may place wafer 322 on lift pins 328, extended from chuck 330.

In at least one implementation, pedestal 332 may be previously lowered to a home position to receive wafer 322 transferred from vacuum transfer module 302. In at least one implementation, home position may be the furthest distance from chuck 330 is from showerhead 334. In at least one implementation, wafer 322 may be transferred from another process station outside of process module 304. When pedestal 332 is lowered to home position, in at least one implementation spatial sensor 314 may be pivoted to an oblique angle for overhead viewing transfer of wafer 322, as indicated by the rotated dashed outline of spatial sensor 314 and its view cone in FIG. 3A. In at least one implementation, spatial sensor 308 may have an edge-on view of wafer 322. In at least one implementation, spatial sensor 308 may capture vertical motion of wafer 322 and end effector 326.

FIG. 3B illustrates a profile view of process system 300 after a wafer transfer and during a plasma-enhanced chemical vapor deposition (PECVD) process, according to at least one implementation. In at least one implementation, pedestal 332 has been raised to a process position. In at least one implementation, prior to start of the PECVD process, wafer 322 is near showerhead 334, as shown. In at least one implementation, prior to commencement of a process, robot arm 324 and end effector 326 are retracted into vacuum transfer module 302 and may assume a stowed position, as shown. In at least one implementation, slit valve 320 may be closed.

In at least one implementation, spatial sensor 306 may capture an edge-on view of the PECVD process, including plasma 336 that has been ignited and sustained by radio frequency energy radiating from showerhead 334. In at least one implementation, spatial sensor 306 may capture video images of film growth on wafer 322. In at least one implementation, spatial sensor 306 may capture video images that may be analyzed for particle deposition and growth on an edge of wafer 322, and/or on chuck 330. In at least one implementation, spatial sensor 306 may be operable to resolve tens of microns per pixel, enabling detection of small particles that may nucleate on the edge of wafer 322 or on chuck 330. In at least one implementation, detection of particle growth on wafer 322 and chuck 330 during a PECVD process may be monitored by machine vision software. In at least one implementation, machine learning software may be trained to detect threshold particle sizes by comparison with historical data sets. In at least one implementation, when particle size may be determined to have reached a threshold size, a cleaning operation may be performed. In at least one implementation, system software may flag a clean cycle recommendation to users of the tool (e.g., process system 300), or perform the cleaning operation autonomously.

FIG. 3C illustrates a frontal profile view of a slit valve 340 comprising a mounted spatial sensor 342 on a slide door 346 of slit valve 340, in accordance with at least one implementation. In at least one implementation, a slit valve 340 is substantially similar to conventional slit valves, such as slit valve 320. In at least one implementation, slit valve 340 is mounted on a wall of a process module (e.g., process module 304) that is shared with a vacuum transfer module (e.g., vacuum transfer module 302) attached to the process module. In the illustrative implementation, slide door 346 is shown in the closed position. In at least one implementation, slit valve 340 comprises face plate 344. In at least one implementation, slide door 346 is a moveable plate that opens and closes slit valve 340. In at least one implementation, slide door 346 is located behind face plate 344, visible through slot 348 in face plate 344. Slot 348 extends as an elongated aperture extending horizontally (e.g., in the x-direction) Spatial sensor 342 is mounted on slide door 346, and has visual access to the interior of a process module (e.g., process module 304) (described below). In at least one implementation, spatial sensor 342 may provide visual data for machine measurement of the centering offset of a wafer (e.g., wafer 322) positioned on top of a pedestal (e.g., chuck 330) by a robot arm (e.g., robot arm 324) within process module 304. For example, spatial sensor 342 may provide a view of horizontal position of the wafer. By vertical movement of slide door 346, spatial sensor may capture views of the wafer at various z-heights to obtain an accurate measurement. The function of spatial sensor 342 to aid in centering of a wafer on chuck 330 is described in more detail below.

In at least one implementation, slide door 346 slides downward and upward (e.g., in the z-direction) behind face plate 344 to open and close, respectively. In at least one implementation, slot 348 comprises vertical extension 350, extending in the z-direction below slot 348. Vertical extension 350 can accommodate downward movement of spatial sensor 342 when slide door 346 moves downward to open slit valve 340.

In the illustrative implementation, shown in FIG. 3C, spatial sensor 342 and vertical extension 350 are positioned substantially centrally within slit valve 340. In at least one implementation, spatial sensor 342 and vertical extension 350 may be positioned at any suitable location along slot 348. For example, spatial sensor 342 may be positioned near one end of slot 348.

FIG. 3D illustrates a rear profile view of slit valve 340, in accordance with at least one implementation. In at least one implementation, optical window 352 extends through slide door 346, allowing a view into process module 304 for spatial sensor 342, mounted on the opposing face of slide door 346, as shown in FIG. 3C. In at least one implementation, optical window 352 may comprise an optically transparent material such as fused silica, quartz, or borosilicate glass. Optical window 352 may protect spatial sensor from extreme conditions that may occur within process module 304, for example, such as exposure to high temperatures and exposure deposition precursor materials.

FIG. 3E illustrates a frontal profile view of slit valve 340 shown in an open position, according to at least one implementation. In at least one implementation, slot 354 is opened to the vacuum transfer module (e.g., vacuum transfer module 302) when slide door 346 is lowered to an open position. In the open position, spatial sensor 342 is lowered into vertical extension 350, permitting slide door 346 to be lowered, exposing slot 354. The dark area behind slot 354 is the interior of process module 304, for example. Slot 354 may be wide to allow passage of a robot arm and/or end effector holding a wafer into the process module.

FIG. 3F illustrates an overhead view of process system 300, incorporating slit valve 340 and spatial sensor 342 mounted on slit valve 340. The overhead view in FIG. 3F shows sight angles of orthogonally arranged spatial sensors 342 and 356, where spatial sensor 342 is configured to view wafer 322 on chuck 330 from a perspective view in the x-direction. An exemplary view angle or view cone of spatial sensor 342 is indicated by the solid lines fanning out from the position of spatial sensor 342 on slit valve 340. Spatial sensor 342 is mounted on slide door 346, as shown in FIGS. 3C and 3E. Spatial sensor 356 is external to process module 304 and has a view into the interior of process module 304 through viewport window 358. In at least one implementation, spatial sensor 356 is configured to view wafer 322 on chuck 330 from a perspective in the y-direction, orthogonal to the view of spatial sensor 342. An exemplary view angle of spatial sensor 356 through viewport window 358 is indicated by the broken lines fanning out from viewport window 358.

In at least one implementation, spatial sensor 342 has an optical axis 343, extending in a straight line from a first optical center of spatial sensor 342, whereas spatial sensor 356 has an optical axis 357 extending in a straight line from a second optical center of spatial sensor 356. In the illustrative implementation, optical axis 343 is orthogonally oriented (e.g., at a 90-degree angle) with respect to optical axis 357. In at least one implementation, optical axis 343 may be oriented at a general angle with respect to optical axis 357, where the angle ranges between zero degrees and 180 degrees.

In at least one implementation, vacuum transfer module 302 contains robot arm 324 and end effector 326 is attached to the distal end of robot arm 324. In at least one implementation, an additional spatial sensor may be mounted on end effector 326 (not shown).

FIG. 3G illustrates orthogonal perspective views 360 and 370 of wafer 322 captured by spatial sensor 342 and spatial sensor 356, in accordance with at least one implementation. In the illustrative implementation, wafer 322 is mounted on chuck 330 (not shown). Perspective view 360 is elliptical in shape due to the z-height of spatial sensor 342 above the plane of wafer 322. In at least one implementation, perspective view 360 may be an exemplary view of wafer 322 obtained by spatial sensor 342 mounted on slit valve 340, for example. Perspective view 370 is also elliptical in shape, again due to the z-height of spatial sensor 356 relative to wafer 322. In at least one implementation, perspective view 370 may be an exemplary view of wafer 322 obtained by spatial sensor 356 viewing wafer 322 through viewport window 358, as shown in FIG. 3F. In the illustrative implementation of FIG. 3G, the position of wafer 322 is shown relative to a centering mark or reference contour 365. For example, reference contour 365 may be an inner sidewall of an edge ring centered on chuck 330, for example. In the illustrative implementation, wafer 322 is not centered within tolerances. For example, spatial sensor 342 captures an image such as perspective view 360, whereby a distance Δx may be measured by machine vision software between an edge 366 of wafer 322 and reference contour 365. In at least one implementation, reference contour 365 may be a circular mark on chuck 330, a teach fixture, or an inner sidewall of an edge ring or a calibration ring. In at least one implementation, distance Δx includes an acentric component in the x direction (e.g., assuming a cartesian coordinate system), whereby the acentric component may be a fraction of Δx. For example, Δx may be 0.67 mm. The acentric component may be an offset from center, where at center Δx may be exactly 1.000 mm. Thus, the acentric component may be −330 microns, for example. Thus, wafer 322 may be off center by −330 microns in the x-direction.

Similarly for perspective view 370 obtained by spatial sensor 356, a measure Δy may also be derived by machine vision software. For example, Δy may be measured at 1.678 mm. At center, Δy is 1.000 mm, as is the case for Δx. Thus, the acentric component in the y-direction is +678 microns.

Also indicated in FIG. 3G are angles of inclination α and β for spatial sensors 342 and 356, respectively. In at least one implementation, angles of inclination α and β are substantially equal, but this is not a necessary condition. In at least one implementation, angles of inclination α and β are referenced to a horizontal plane parallel with wafer 322, for example. Angles α and β may be adjusted along a longitude (e.g., in the z-direction). In at least one implementation, angles α and β may be independently adjusted. For example, angle of inclination α may be varied during vertical movement (e.g., opening and closing) of slide door 346 of slit valve 340. Angle β may be fixed in some implementations, The angles of inclination α and β may be adjusted for highest accuracy of measurement. For example, pixel resolution may improve by viewing wafer 322 at a lower angle of inclination α or β than a higher angle of inclination. Machine vision software may more accurately determine Δx and Δy, for example.

Besides the angle of inclination of the spatial sensors, other factors that determine image resolution may include the inherent pixel resolution of spatial sensors 342 and 356. For example, spatial sensors 342 and 356 may be a 12-megapixel camera. Higher pixel resolution of the spatial sensor increases measurement accuracy. In addition to inherent pixel resolution of spatial sensors, lens focal length also determines measurement resolution of spatial sensors 342 and 356. For example, a centering tolerance callout may be 50 microns, whereby Δx and Δy are both 1.000 +/−0,050 mm when wafer 322 is centered. The distance of 50 microns (0.050 mm) may be 0.8 pixels for a 12-megapixel camera having a focal length of 12 mm. The resolution of 0.8 pixels for a 50-micron distance may not be sufficient resolution for an accurate distance measurement by machine vision software. By contrast, for a 12-megapixel camera having a 50 mm focal length, a distance of 50 microns is spanned by 4.8 pixels. This pixel resolution can be sufficient for accurate distance measurement by machine vision software. In at least one implementation, spatial sensors 342 and 356 have an adjustable zoom lens, whereby the focal length may be adjusted, for optimizing resolution. At a lower angle of inclination, pixel resolution may increase to 5.5 pixels for 50 microns, further improving measurement accuracy. The 50-mm focal length enables spatial sensors to zoom into the region of interest, increasing pixel resolution. Spatial sensors having higher pixel resolution may be capable of finer resolution. In at least one implementation, to enable variable zoom adjustment. spatial sensor 342 and spatial sensor 356 have zoom capability, whereby a first focal length of spatial sensor 342 is variable and a second focal length of spatial sensor 356 is variable. The various design parameters and numbers are provided as an example and may depend on camera sensor design (e.g., pixel pitch, etc.), and are not meant to be limiting.

In FIG. 3G, view 380 is a composite overhead (plan) view of wafer 322 derived by combining orthogonal elliptical perspective views 360 and 370 and mathematically transforming the composite image into a circular overhead view 380 by system software or machine vision software. This is indicated in the figure by the “plus” sign (+) between perspective views 360 and 370, and an “equal” sign (=) between perspective view 370 and view 380. In at least one implementation, view 380 shows both Δx and Δy and the eccentricity of wafer 322 relative to reference contour 365. Wafer 322 may be centered by bringing end effector 326 on robot arm 324 into process module 304 and repositioning wafer 322 by calculation of acentric offsets in Δx and Δy, and making a correction through assigning new coordinates to robot arm 324. An autocorrection process for wafer centering may be developed by software training through repetition of a placement sequence depicted in FIG. 3H-3J, described below.

FIGS. 3H-3J illustrate a sequence of exemplary loading operations for transferring a wafer from a vacuum transfer module to a process module, where slit valve 340 and spatial sensor 342 mounted on slit valve 340 is employed. Wafer loading operations illustrated in FIG. 3H-3J may be repeated one or more times to center the wafer based on visual measurements by orthogonally-oriented spatial sensors 342 and 356. Operations shown in FIGS. 3H-3J may also be employed in training system software to operate wafer transfer operations autonomously and autocorrect wafer centering. The training data may be based on machine supervision via spatial sensors 342 and 356 as described above, and may be incorporated into system software to run processes autonomously, in accordance with at least one implementation.

FIG. 3H illustrates a profile view of process system 300 in a first loading operation preparing to transfer wafer 322 from vacuum transfer module 302 to process module 304. In the illustrative implementation, process module 304 comprises spatial sensor 342 mounted on slide door 346 of slit valve 340. In the illustrated operation, wafer 322 is to be transferred from vacuum transfer module 302 to process module 304. Robot arm 324 is poised within vacuum transfer module 302, holding wafer 322 on end effector 326. In the illustrative implementation, slit valve 340 is closed, with slide door 346 in the raised position. Spatial sensor 342 has a view into the interior of process module 304. Within the view angle, chuck 330 is visible. Lift pins 328 may be partially raised over chuck 330 for receiving wafer 322.

In at least one implementation, an external orthogonally oriented spatial sensor, such as spatial sensor 356 shown in FIG. 3G, also has a view of chuck 330 from a viewport window on an orthogonal sidewall of process module 304, such as viewport window 358 shown in FIG. 3G. In at least one implementation, machine vision software may analyze combined images recorded by both spatial sensor 342 and spatial sensor 356 to determine dimensions and center position of chuck 330.

FIG. 3I illustrates a profile view of process system 300 in a second loading operation, where wafer 322 is transferred from vacuum transfer module 302 to process module 304, where it is placed on chuck 330. In the illustrated operation, slit valve 340 is opened by lowering slide door 346. Robot arm 324 is commanded to move end effector 326 through slit valve 340 into process module 304. In at least one implementation, coordinates calculated by machine vision software from the previous operation illustrated in FIG. 3H may be sent to the motor driver for robot arm 324 to center wafer 322 on chuck 330. In at least one implementation, wafer 322 may be approximately centered due to some inaccuracies in the placement of wafer 322 by robot arm 324. For example, Δx may not equal Δy, where Δx and Δy are x and y components of predetermined distance between the edge of wafer 322 and a reference contour, such as reference contour 365 shown in FIG. 3G, and an acentric offset in both Δx and Δy may be present. A reference contour may correspond to an edge ring for example, or a centering on chuck 330 with respect to showerhead 334, for example. A predetermined tolerance for acentric offset may be encoded within the system software. For example, a maximum acentric offset of +/−50 microns (0.050 mm) may be encoded, where Δx and Δy are also encoded into the system software. For example, Δx and Δy may be predetermined to equal 1.000 +/−0.050 mm. For example, the edge of wafer 322 is to be centered on chuck 330 such that a distance from the edge of wafer 322 to an inner sidewall of an edge ring is 1.000 +/−0.050 mm.

FIG. 3J illustrates a profile view of process system 300 in a third loading operation, where robot arm 324 and end effector 326 are retracted into vacuum transfer module 302. Slit valve 340 is closed, whereby slide door 346 is raised, bringing spatial sensor 342 into viewing position. A view angle for spatial sensor is shown in FIG. 3J. In at least one implementation, a second spatial sensor, such as spatial sensor 356 (not shown), may be simultaneously viewing wafer 322 from a side viewport window (e.g., viewport window 358) in an orientation orthogonal to spatial sensor 342.

In at least one implementation, spatial sensors 342 and 356 may record zoomed views of the position of wafer 322 with respect to a reference contour on chuck 330. For example, spatial sensors 342 and 356 may have a pixel resolution of 12 megapixels and a lens focal length of 50 mm. Such optical parameters for spatial sensors 342 and 356 may enable sufficient pixel resolution for machine vision software to accurately measure Δx and Δy, determining any acentric offset. If machine vision software determines that acentric offset is present in Δx and/or Δy, then system software may re-iterate the wafer loading sequence, returning to the first operation illustrated in FIG. 3H, for example.

Here, wafer 322 is not queued within vacuum transfer module 302 but already loaded within process module 304. However, a sequence of raising wafer 322 from chuck 330, opening slit valve 340, extending robot arm 324 and end effector 326 into process module 304 to retrieve wafer 322 and repositioning wafer 322 on chuck 330 to compensate the initial acentric offset (as described above, for example), may be performed. Thus, operations illustrated in FIG. 3H-3J may be repeated to center wafer 322 within tolerances. In at least one implementation, further cycles of loading operations illustrated in FIG. 3H-3J may be repeated if necessary to center wafer 322 within tolerances. In addition, loading operations illustrated in FIG. 3H-3J may be employed for system training for automated wafer loading operations in wafer processing, for example.

FIG. 3K illustrates a flow chart 390 summarizing an exemplary sequence of loading and centering operations for robot teaching, in accordance to at least one implementation. At operation 391, slit valve (e.g., slit valve 340) having a spatial sensor (e.g., spatial sensor 342) mounted on the slide door is opened for transfer of a wafer (e.g., wafer 322) from a vacuum transfer module, such as vacuum transfer module 302, into a process module, such as process module 304. The transfer is effectuated by robot arm 324, for example. At operation 392. the wafer is transferred into the process module and placed on a pedestal, such as chuck 330.

At operation 393, the slit valve is closed. During transit of the slide door, whereby the spatial sensor moves upward, the mounted spatial sensor may record image frames of the wafer at various z-heights. The various z-heights may affect image resolution. In robot training operations, a best z-height may be determined for most accurate dimension measurements by machine vision software.

At operation 394, image data from the slit valve-mounted spatial sensor is combined with image data from a viewport spatial sensor, such as spatial sensor 356. In at least one implementation, spatial sensor 356 is orthogonally oriented with respect to spatial sensor 342. As noted above, the wafer image viewed by both spatial sensors may be elliptical (e.g., see FIG. 3G). Combined images may be transformed to produce an overhead view of a circularly-shaped wafer. In at least one implementation, the offsets Δx and Δy are computed. Spatial sensors may have sufficient image resolution to perform accurate measurements, as noted above. Any acentric offsets embedded within Δx and Δy may be calculated by machine vision software (also machine learning software) or other software modules within the system software.

At operation 395, the decision block embodies a determination of adherence to centering tolerances may be made by machine vision software or other software modules within a system software for the process system. For example, Δx and Δy may be computed with respect to a reference contour, and software determination of adherence to centering tolerances (e.g., a maximum acentric offset of 50 microns) encoded in the software may be performed. If Δx and/or Δy are out of spec, then the decision block switches program flow to operation 396. If Δx and Δy are both within spec, then program flow is transferred to operation 398.

At operation 396, machine vision or machine learning software computes a correction for the eccentricity, and transfers the correction as a coordinate update to the robot arm. At operation 397, the slit valve is opened and the robot arm is now commanded to extend into the process module. The wafer is then lifted off the pedestal by the lift pins, then lifted by the end effector. The robot arm may reposition the wafer according to the new coordinates taught to the robot to make the centering correction. For example, the robot arm may move the wafer in opposition to the acentric offset in both dimensions. After the correction is made, program control is returned again to operation 393.

If the decision block determines that the wafer is centered within specification, then program flow is transferred to operation 398. At operation 398, the robot coordinates (e.g., coordinates of end effector falling within centering specs) may be updated and the robot coordinates recorded into a database or a log by machine learning software or system software.

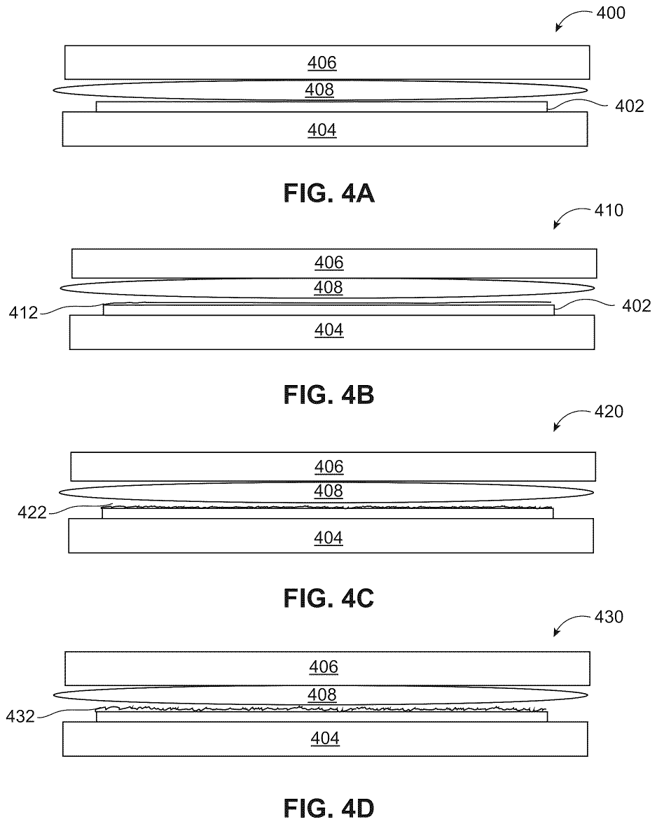

FIG. 4A illustrates an exemplary image 400 of a PECVD process captured by a spatial sensor such as spatial sensor 306, in accordance with at least one implementation. In at least one implementation, image 400 may be captured during a PECVD process performed in a pristine or recently cleaned process module, such as process module 304. In at least one implementation, image 400 may be a video frame taken from a video stream output by spatial sensor 306. In at least one implementation, image 400 comprises wafer 402 on chuck 404. In at least one implementation, wafer 402 is below showerhead 406. In at least one implementation, plasma 408 is between showerhead 406 and wafer 402. In at least one implementation, no detectible particle growth has occurred from past PECVD cycles.

FIG. 4B illustrates an exemplary image 410 of a PECVD process captured by a spatial sensor such as spatial sensor 306, in accordance with at least one implementation. In at least one implementation, image 410 has been captured during a later PECVD process performed in the same process module after several PECVD process cycles have been performed since capture of previous image 400. In at least one implementation, edge growth 412 may begin to be detected as particle sizes may exceed the minimum resolution of a spatial sensor employed to view the process edge-on (e.g., spatial sensor 306).

FIG. 4C illustrates an exemplary image 420 of a PECVD process captured by a spatial sensor such as spatial sensor 306, in accordance with at least one implementation. In at least one implementation, image 420 may be captured during a PECVD process performed in the same process module after several PECVD process cycles have been performed since capture of image 410, shown in FIG. 4B. In at least one implementation, particle sizes in edge growth 422 may be larger than edge growth 412 captured in image 410 in FIG. 4B. In at least one implementation, many particles have grown to a size where they are now visible in image 420. In at least one implementation, an average particle size may not be large enough to necessitate a chamber clean.

FIG. 4D illustrates an exemplary image 430 of a PECVD process captured by a spatial sensor such as spatial sensor 306, in accordance with at least one implementation. In at least one implementation, image 430 has been captured during a PECVD process performed in the same process module after several PECVD process cycles have been performed since capture of image 420, shown in FIG. 4C. In at least one implementation, particle sizes in edge growth 432 may be larger than edge growth 422 captured in image 420 in FIG. 4C. In accordance with at least one implementation, particle sizes may have reached an exceeded a threshold average particle size. In at least one implementation, based on the raw data captured by the spatial sensor, system software may flag a recommendation for a clean cycle to users of the tool (e.g., process system 300), or may autonomously initiate a clean cycle, according to at least one implementation.

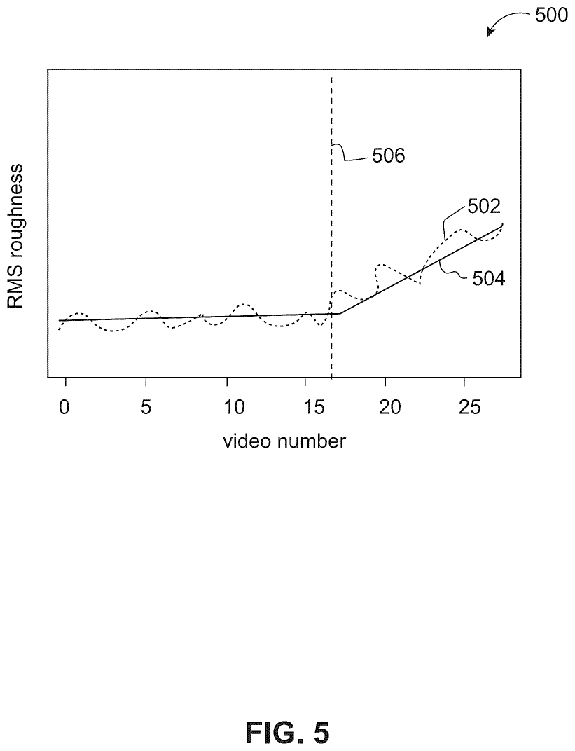

FIG. 5 illustrates plot 500 tracing time evolution of particle buildup on a wafer edge or on the edge of a chuck, in accordance with at least one implementation. In at least one implementation, particles may be from debris falling from a showerhead (e.g., showerhead 334) onto a wafer. In at least one implementation, curve 502 is an exemplary trace of average surface roughness (e.g., root mean square (rms) surface roughness) measured in a succession of video frames captured in successive PECVD runs. In at least one implementation, curve 504 may be an averaged or smoothed plot of the data on which curve 502 is based. In at least one implementation, curves 502 and 504 are plotted against a video number series. In at least one implementation, video numbers represent video frames captured during successive PECVD processes in a same process module, and therefore time. In at least one implementation, line 506 marks the appearance in a series of videos of particles large enough to measure and track. In at least one implementation, beyond line 506, particle size, measured by rms roughness, for example, measured by software, grows steadily. In at least one implementation, particle size growth may be substantially linear. In at least one implementation, a particle size threshold may be determined by statistical methods, for example, at which point a clean cycle may be initiated.

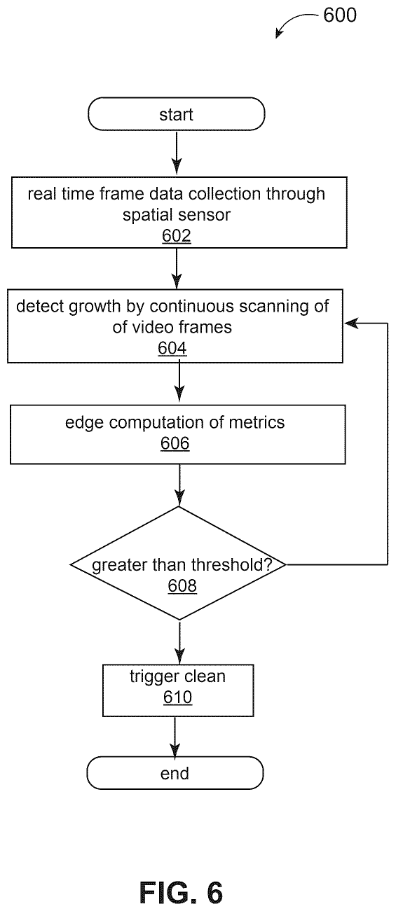

FIG. 6 shows flow chart 600 illustrating an exemplary method to determine a particle size threshold for initiating a clean cycle, in accordance with at least one implementation.

At operation 602, in at least one implementation, video data may be collected by a spatial sensor (e.g., a camera) having an edge-on view of a process, (e.g., a PECVD process), such as spatial sensor 306 in FIG. 3B. In at least one implementation, one or more spatial sensors (e.g., spatial sensor 306) is/are electronically coupled to a computing device. In at least one implementation, the computing device comprises a dedicated microprocessor or a general-purpose microprocessor. In at least one implementation, one or more spatial sensors (e.g., spatial sensor 306) is/are operable to send a stream of real time video data from monitored process to buffers on a memory coupled to a processor of computing device. In at least one implementation, machine vision software may manage streaming video data to parse the data into individual video frames.

At operation 604, in at least one implementation, machine vision software may comprise algorithms to detect particle growth. In at least one implementation, machine vision software may comprise one or more image analysis algorithms that can recognize particles and measuring their size (e.g., by measuring surface roughness). In at least one implementation, as real time video data is fed from one or more spatial sensors to memory on computing device, acquired video frames may be scanned in real time to measure surface roughness. In at least one implementation, image analysis software may be capable of surface roughness analysis to measure presence of particles on a surface, and to determine average particle size In at least one implementation, surface roughness may be measured in a time-lapse manner. In at least one implementation, particle size data measured during a current process run may be compared to prior process runs to determine whether an increasing trend in particle size is occurring. In at least one implementation, particle size is determined to be increasing from run to run, then machine supervisory software may wait until a critical particle size is reached before signaling that a clean operation of the process chamber is advised, or autonomously trigger a clean operation of the process chamber.

At operation 606, in at least one implementation, video data are analyzed to reconstruct images of edge-on view of the wafer under process. In at least one implementation, edge-on views may show emerging particle growth as shown in FIGS. 4A-4D. In at least one implementation, system software may comprise one or more algorithms operable to mathematically analyze video frames to determine particle growth. In at least one implementation, one or more algorithms are operable to compute average particle size.

In at least one implementation, during normal film deposition, such as during a PECVD process, deposition may be controlled in such a way that surface roughness of the film is maintained below a predetermined threshold. In at least one implementation, in the absence of particles, deposited film may have an average or rms surface roughness below a specified threshold.

A presence of particles on a wafer or film growing on a wafer may indicate a state of cleanliness of a process module. As deposition products may grow on surfaces within a process module over numerous process cycles, particles may flake off from those deposits during film deposition processes taking place within the process module. For example, film growth may occur on the showerhead of a process station. Particles may flake off the showerhead and fall on a wafer during a PECVD process, for example. These particles may be observed by spatial sensors viewing the wafer edge-on (e.g., spatial sensors 230, 232, 258, 260, FIG. 2B). In at least one implementation, these particles may be observed by spatial sensors viewing the wafer from overhead (e.g., spatial sensor 250, FIG. 2B).

In at least one implementation, deposition products may build up on surfaces within the process module as process cycles continue between clean operations. With the addition of more process cycles, deposits on surfaces such as showerheads (e.g., showerheads 210 and 220) within the process module may grow thicker. Larger particles may flake off the thick deposits on chamber walls and eventually landing on growing films on wafers under process. In at least one implementation, a clean operation of the process module is indicated.

In at least one implementation, detection of particles on a growing film may be indicated by surface roughness measurements exceeding a predetermined threshold. For example, particle detection may be made by computation of average or rms edge roughness from wafer edge images reconstructed from scanned video data. In at least one implementation, algorithms contained within machine vision software or in other software modules may measure average or rms surface roughness that may exceed the predetermined threshold value if particles are present that are larger than 1 or 2 micrometers, for example. In at least one implementation, a threshold surface roughness value may be deduced from surface roughness data plots such as plot 500 shown in FIG. 5. For example, a threshold rms surface roughness value may be taken at an intersection of line 506 and curve 504 in FIG. 5, where curve 504 begins to climb upward.

At operation 608, in at least one implementation, system software may compare averaged particle size from computation performed at operation 606 to a predetermined threshold value. In at least one implementation, if an averaged particle size value, such as rms roughness, for a video frame is below the threshold value, algorithm returns to operation 604. In at least one implementation, video frames may continue to be acquired in real time, scanned, and analyzed.

At operation 610, in at least one implementation, system software may determine that averaged particle size may have reached or surpassed a predetermined threshold value. In at least one implementation, at this juncture, system software may initiate a clean operation for the process module. In at least one implementation, system software may flag users of tool to manually perform clean operation. In at least one implementation, system software may execute an automatic clean operation autonomously.

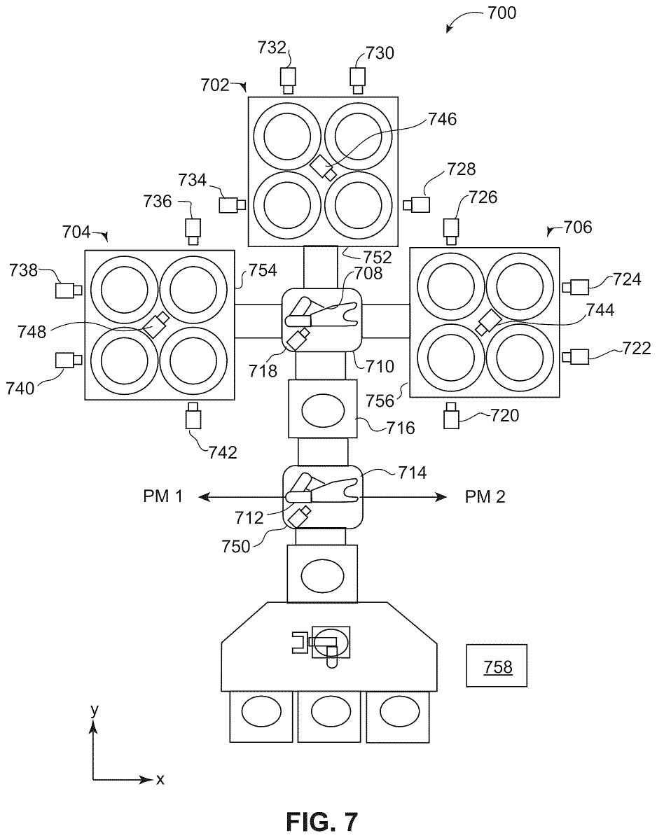

FIG. 7 illustrates a schematic diagram of process system 700, in accordance with at least one implementation. In at least one implementation, process system 700 is an exemplary multi-module process system, comprising process modules 702, 704, and 706. In at least one implementation, process modules 702, 704, and 706 are multi-station process modules. In at least one implementation, process modules 702, 704, and 706 are quad station modules (e.g., comprising four process stations). In at least one implementation, process modules 702, 704, and 706 are served by robot arm 708 housed in vacuum transfer module 710.

In at least one implementation, robot arm 708 may receive wafers by hand-off from robot arm 712 housed in vacuum transfer module 714. In at least one implementation, robot arm 712 may transfer wafers into load lock 716. In at least one implementation, robot arm 708 may retrieve wafers loaded into load lock 716 by robot arm 712, bringing them into vacuum transfer module 714. In at least one implementation, wafers may be transferred into process modules 702, 704, and 706 by robot arm 708 under supervision by any of spatial sensors 718, 720, 722, 724, 726, 728, 730, 732, 734, 736, 738, 740, 742, 744, 746, 748, or any combination thereof. In at least one implementation, spatial sensors 744, 746, and 748 are mounted within process modules 702, 704, and 706, respectively. In at least one implementation, spatial sensors 744, 746, and 748 have overhead and/or oblique views of wafer transfer and positioning operations taking place within process modules 702, 704 and 706, respectively.

In at least one implementation, robot arm 712 may service other process modules (e.g., PM1 and PM2) under supervision by spatial sensor 750 within vacuum transfer module 714. In at least one implementation, robot arms 708 and 712 may transfer wafers through slit valves (not shown) within walls 752, 754, and 756 of process modules 702, 704, and 706, respectfully. In at least one implementation, walls 752, 754, and 756 may separate process modules 702, 704, and 706 from vacuum transfer module 710. In at least one implementation, machine interface 758 may be included to receive video data from all spatial sensors and send commands to motor-actuated components, such as robot arms 708 and 712. In at least one implementation, machine interface 758 may also provide control interfacing to motor-actuated devices not shown in FIG. 7, such as slit valves, spindles, end effectors, pedestals and chucks within process modules 702, 704, and 706. In at least one implementation, chucks may comprise electrostatic clamping electrodes, also controlled by machine interface 758.

In at least one implementation, machine interface 758 may comprise a processor and memory. In at least one implementation, machine interface 758 may comprise a video interface coupled to spatial sensors. In at least one implementation, machine interface 758 may comprise an interface coupled to actuators (e.g., electric motors) driving robot arms, end effectors, pedestals, spindles, slit valves and chucks.

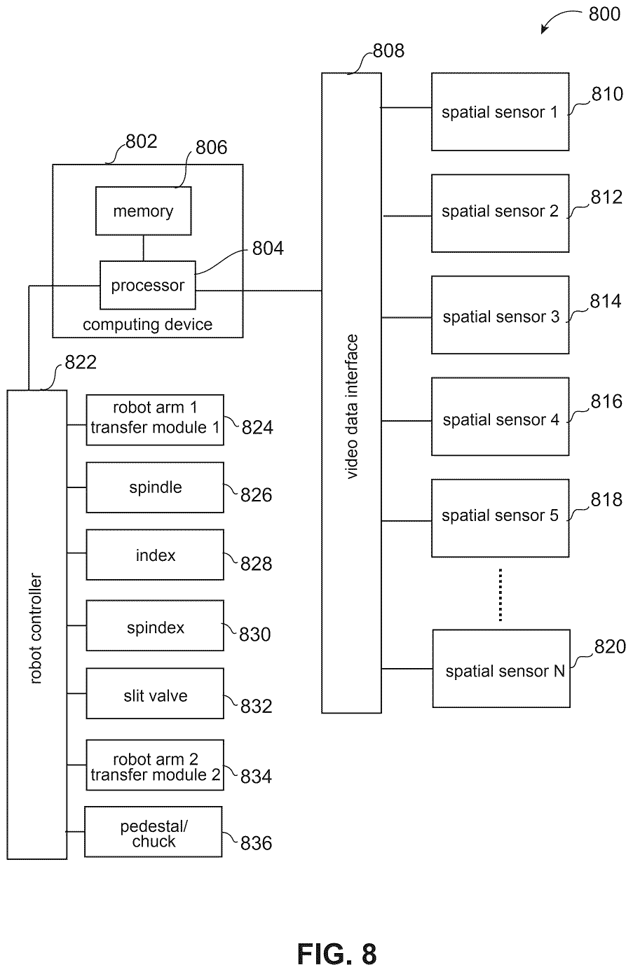

FIG. 8 illustrates a hardware block diagram of process control system 800 for operation of process systems described herein, such as process system 700, in accordance with at least one implementation. In at least one implementation, process systems may comprise at least one process module, vacuum transfer module, load lock, pedestal, robot arm, spindle, chuck, and one or more spatial sensors. In at least one implementation, computing device 802 may be a central component within process control system 800. In at least one implementation, computing device 802 may comprise processor 804 and memory 806. In at least one implementation, memory 806 may be electronically coupled to processor 804. In at least one implementation, processor 804 may be, at least in part, a dedicated microprocessor, such as one or more (distributed) microprocessors embedded within actuator control circuitry. In at least one implementation, processor 804 may be, at least in part, a general-purpose microprocessor, such as a central processing unit (CPU) in a general-purpose computer. In at least one implementation, processor 804 may be electronically coupled to a system processor that may coordinate multiple systems.

In at least one implementation, process control system 800 comprises video data interface 808. In at least one implementation, video data interface 808 may be electronically coupled to processor 804. In at least one implementation, video data interface 808 may be electronically coupled to spatial sensors 810, 812, 814, 816, 818, and 820. In at least one implementation, video data interface 808 may mediate transfer of video data to processor 804. In at least one implementation, video data interface 808 may buffer video data streams arriving in real time from spatial sensors 810-820. In at least one implementation, video data interface 808 may parse video data into frames and transfer video frames to processor 804.

In at least one implementation, machine vision software comprising machine-readable binary code, executable by processor 804, may be stored in memory 806. In at least one implementation, machine-readable binary code may be embodied by machine vision software comprising algorithms operable to analyze video frames for particle growth, for example. In at least one implementation, machine vision software stored within memory 806 may comprise one or more algorithms to measure movement of robotic parts within a process system such as process system 700.

In at least one implementation, memory 806 may comprise machine readable binary code embodied by machine learning software. In at least one implementation, machine learning software may comprise training algorithms that may learn positional data of movable components such as robot arms, pedestals, spindle indexing, slit valves, etc., during training operations.

In at least one implementation, machine learning software may share video data with machine vision software. In at least one implementation, video data may also be stored in memory 806, for example as video frames. In at least one implementation, machine learning software may hand off (e.g., teach) wafer transfer and particle growth measurement data to system software. In at least one implementation, system software may be stored elsewhere in the system, and may be executed by a system processor. In at least one implementation, once positional data are taught to system software, system software may take over autonomous control of wafer transfer, for example.

In at least one implementation, processor 804 may be electronically coupled to robot (or machine) controller 822 to interface to motor-controlled devices. In at least one implementation, robot controller 822 may provide interface circuitry for interfacing devices such as robot arm #1 824, spindle 826, spindle index 828, spindex 830, slit valves 832, robot arm #2 834, and pedestal and chuck combination 836. In at least one implementation, robot controller 822 may receive digital signals from processor 804 and convert from digital voltage signals to analog voltages. In at least one implementation, voltage signals may be power-amplified to drive motors.

In at least one implementation, processor 804 may autonomously control devices coupled to robot controller 822. In at least one implementation, processor 804 may perform an intermediary role in controlling devices coupled to robot controller 822. For example, in at least one implementation, processor 804 may receive commands issued by a higher-level system processor to execute wafer transfer software routines stored within memory 806. In at least one implementation, data from machine learning software may be stored within memory 806 and accessed by processor 804 for autonomous execution of wafer transfer operations such as pedestal z-height positioning and automatic wafer centering (e.g., AWC) on chucks receiving the wafers.

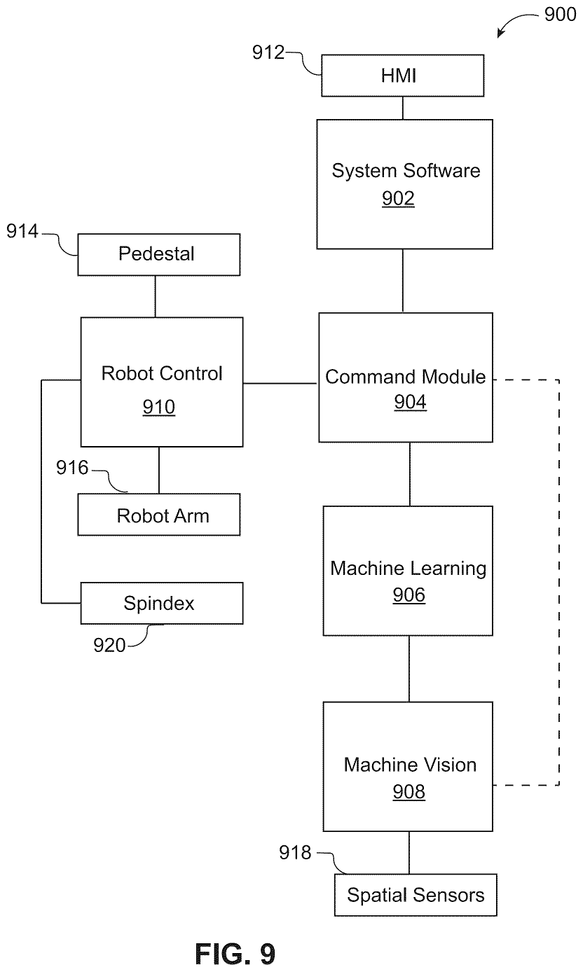

FIG. 9 illustrates software block diagram 900 showing an exemplary organization and hierarchy of system software for autonomous teaching and operation of process systems, in at least one implementation. In at least one implementation, system software 902 is at the top position of a module hierarchy stack comprising command module 904, machine learning module 906 and machine vision module 908. In at least one implementation, command module 904 may supervise training and passes newly acquired information to machine learning module 906. In at least one implementation, command module 904 also communicates with robot controller 910, passing learned coordinates to robot control software contained within robot controller 910. In at least one implementation, command module 904 commands machine learning module 906, which in turn oversees machine vision module 908. In at least one implementation, machine learning module 906 may mediate data transfer from machine vision module 908 to command module 904. In at least one implementation, command module 904 may have direct access to machine vision module 908, as indicated by the dashed connection link. In at least one implementation, newly learned robot arm movement coordinates or memory addresses pointing to robot arm movement coordinates that are stored in a memory block may be passed to robot controller 910 by command module 904.

In at least one implementation, human operators may initiate machine teaching events through human-machine interface (HMI) 912 interfaced to system software 902. In at least one implementation, HMI 912 may be a keyboard, a touchscreen a speech to text or speech recognition interface, or any combination thereof. For example, a field engineer may enter new z-coordinates for positioning (e.g., raising or lowering) of pedestal 914 during programming of a new process or reprogramming an existing process to HMI 912. In at least one implementation, system software 902 may receive new process instructions programmatically by retrieval from a database. In at least one implementation, the new process instructions may contain new pedestal coordinates, for example. In at least one implementation, knowledge of the new pedestal coordinates must be taught to robot controller 910 so that wafer handoff can take place between robot arm 916 and pedestal 914.

In accordance with at least one implementation, command module 904 may be prompted by system software 902 to perform an automated machine teaching event, whereby robot controller 910 is re-calibrated. In at least one implementation, the automated machine learning event comprises learning the new pedestal coordinates by machine learning module under supervision by command module 904. In at least one implementation, the learned coordinates may be stored and recalled by command module 904 for future wafer transfer operations conducted during the new or modified process. In at least one implementation, pedestal coordinates specifying z-height positions of pedestal 914 may be passed to command module 904 from system software 902. In at least one implementation, command module 904 may command machine learning module 906 to invoke machine learning algorithms stored in memory. In at least one implementation, machine learning algorithms may comprise learned robot arm coordinate data sets for moving robot arm 916 along a trajectory between a vacuum transfer module (e.g., vacuum transfer module 302) and pedestal 914.

In at least one implementation, during conventional pendant teaching, a human teacher may manually control movement of the robot arm by jogging movements in intended directions by a joystick on a teaching pendant. The human teacher may create a trajectory path of the robot arm and its end effector by moving the robot arm with the joystick. The human teacher may steer the robot arm from one positional (e.g., xyz) coordinate to a next positional coordinate and may store relevant positional coordinates along the trajectory by manually capturing them with the teaching pendant (e.g., by pressing a button at key positions along the trajectory). The manually chosen positional coordinates may be retrieved by the teaching pendant from robot controller 910, which may keep track of the position of robot arm 916.

In at least one implementation, relevant positional coordinates of the robot arm and/or its end effector are taught to command module 904, for example, by storing them in a memory block accessible by command module 904. In at least one implementation, during future wafer transfer operations, command module 904 may recall these taught positional coordinates and transfer them to robot controller 910. In at least one implementation, robot controller 910 may learn the positional coordinate set for the new robot arm trajectory and autonomously drive actuators in robot arm 916 according to the learned positional coordinate set.

In accordance with at least one implementation, machine-learning driven teaching comprises invocation of machine learning machine learning module 906. In at least one implementation, machine learning module 906 invokes machine vision module 908, which gathers visual data through spatial sensors 918. In at least one implementation, command module 904 may be prompted by system software 902 to initiate a machine learning event. In at least one implementation, this teaching event may also be related to implementation of a new or modified process recipe, requiring adjustment of height (z-coordinates) of pedestal 914. However, in at least one implementation, no human intervention or supervision is involved in the machine learning driven teaching process.

In at least one implementation, a teaching event supervised by command module 904 may be requested by system software 902. In at least one implementation, command module 904 may communicate with machine learning module 906 to obtain positional information of robot arm 916 from machine vision module 908. In at least one implementation, machine vision module 908 may process raw video data streaming from spatial sensor 918, for example. In at least one implementation, command module 904 may direct machine learning module 906 to invoke machine vision module 908, or issue direct commands to machine learning module 906. In at least one implementation, during the teaching event, command module 904 may issue instructions to robot controller 910 to move pedestal 914 to a specified z-coordinate. In at least one implementation, subsequently or simultaneously, command module 904 may instruct robot controller 910 to initiate movement of robot arm 916 toward pedestal 914. In at least one implementation, at least one of spatial sensors 918 may be positioned to watch movement of robot arm 916 in lateral (e.g., x and y) directions, or in a vertical (e.g., z) direction. For example, an overhead spatial sensor, such as spatial sensor 314 (referring to FIG. 3A) may monitor lateral movements of a robot arm (e.g., robot arm 324, FIG. 3A) extending into a vacuum chamber (e.g., process module 304) from a vacuum transfer module (e.g., vacuum transfer module 302). In at least one implementation, a side-mounted spatial sensor, such as spatial sensor 308, may monitor vertical movements of the robot arm.

In at least one implementation, raw video data obtained by the at least one spatial sensor 918 may be stored in memory blocks accessible by machine vision algorithms in machine vision module 908. In at least one implementation, such data may be parsed into frames that are calibrated to map pixels to physical distances. In at least one implementation, machine vision module 908 may comprise image analysis software that is operable to determine the positional coordinates of a marker on the robot arm within the vacuum chamber. For example, the marker may be a structure on the edge effector, such as a pin hole. In at least one implementation, the changing positional coordinates of the moving robot arm may be tracked in some or all video frames. In some implementations, the positional coordinates of the robot arm may be measured relative to a fixed structure or coordinate system within the vacuum chamber.

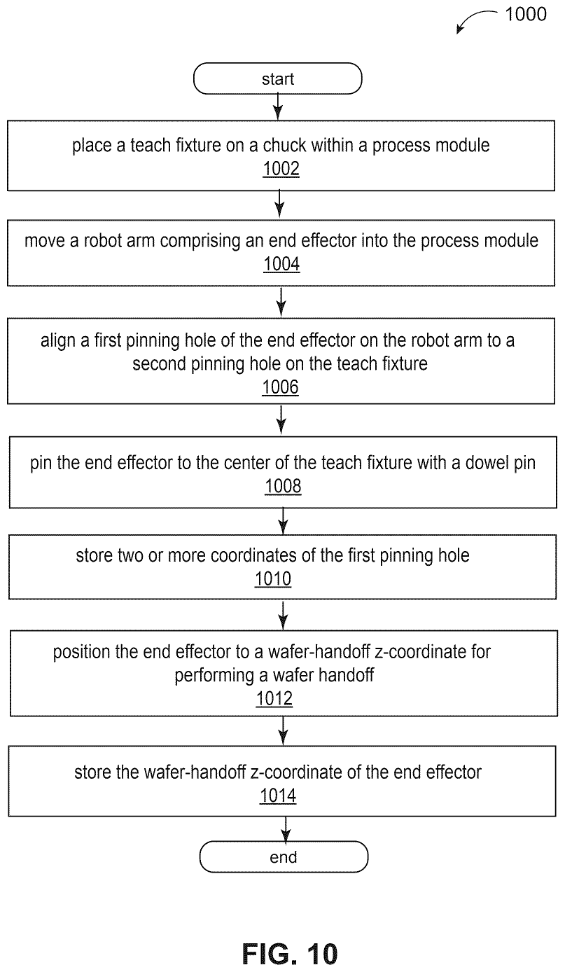

In at least one implementation, command module 904 and/or machine learning module 906 may monitor and supervise the movements of the robot arm. In at least one implementation, the positional coordinates obtained from analysis of the video data (e.g., by algorithms contained within machine vision module 906) may be read by machine learning module 906 and compared to a reference point on pedestal 914. In at least one implementation, the reference point may be a constant, or a derived reference positional coordinate. For example, the reference point may comprise fixed (e.g., constant value) home position x and y coordinates of pedestal 914. In at least one implementation, the reference x and y coordinates of pedestal 914 may correspond to the center of a chuck on top of pedestal 914 (e.g., chuck 208). In at least one implementation, the reference x and y coordinates may correspond to a position on a teach fixture that is placed on the chuck on pedestal 914 (e.g., see description below of operation 1002 in FIG. 10).

In at least one implementation, the z-height of pedestal 914 is adjustable. In at least one implementation, command module 904 may instruct robot controller 910 to change the z-coordinate of pedestal 914 according to new process recipe, for example. In at least one implementation, the updated z coordinate, combined with the reference x and y coordinates, may be a destination or trajectory endpoint coordinate for robot arm 916. In at least one implementation, command module 904 may supervise the movement of robot arm 916 by reading positional coordinates of robot arm 916 and/or its end effector obtained from image analysis in machine vision module 908 either directly or via machine learning module 906. In at least one implementation, based on constant comparisons with destination coordinates, command module 904 may issue instructions to robot controller 910 to correct movement of robot arm as it approaches the destination coordinates. For example, command module 904 may ascertain that robot arm 916 is too low or too high for a wafer handoff to pedestal 914 and determines a correctional change in the z coordinate of robot arm 916. In at least one implementation, this new z coordinate is sent to robot controller 910, which may change the z coordinate of robot arm 916 accordingly. In this manner, command module 904 replaces a human supervisor.

In at least one implementation, the corrected z-coordinate may then be taught to machine learning module 906, which may store the z-coordinate in memory. Similarly, corrections in x and y coordinates of robot arm 916 may be ascertained by command module 904 for the particular trajectory between the vacuum transfer module and pedestal in accordance with the new or modified process. In at least one implementation, these learned positional coordinate data may be taught to machine learning module 906 by command module 904 as a training data set. In at least one implementation, a single set or multiple sets of training data may be obtained by machine learning module 906 through the supervisory activity of command module 904. In at least one implementation, robot controller 910 may communicate with spindle 920 for operations where wafers are transferred between process stations.

FIG. 10 illustrates flow chart 1000 summarizing a method for performing a wafer transfer operation into a process module, in accordance with at least one implementation. Operations of flow chart 1000 may be performed by software, hardware, or a combination of them. In at least one implementation, a process system, such as any of process systems 200, 300, and 700 disclosed herein, may comprise a process module (e.g., process module 202 or 304) comprising one or more process stations (e.g., process stations 204 and 214). In at least one implementation, process stations may comprise a showerhead, and a pedestal supporting a chuck below the showerhead. In at least one implementation, one or more spatial sensors (e.g., spatial sensors 306 and 308) may be located outside of the process module. In at least one implementation, spatial sensors may be adjacent to viewport windows (e.g., viewport windows 226 and 228) within walls of the process module. In at least one implementation, viewport windows may enable spatial sensors to view chucks and/or showerheads within the process module. For example, viewport windows are positionally fixed. In at least one implementation, pedestals may be operable to bring chucks (and wafers clamped thereon) into view of spatial sensors adjacent to viewport windows. In at least one implementation, viewport windows may be located at two or more vertical positions along walls of process module, for example, for externally located spatial sensors to monitor a wafer transfer into the process module at a lower vertical level, and to monitor a PECVD process at a higher vertical level within the process module.

In at least one implementation, at least one overhead spatial sensor may be located within process module. In at least one implementation, at least one overhead spatial sensor may be mounted on a top wall or plate of the process module to obtain overhead and/or oblique views of components within process module. In at least one implementation, at least one overhead spatial sensor may be permanently or semi-permanently located within the interior of process module. In at least one implementation, at least one overhead spatial sensor may be temporarily located within the interior of process module. In at least one implementation, at least one overhead spatial sensor may be attached to a gimbal mechanism mounted on a top wall of process module for enabling swiveling and pivoting of the at least one overhead spatial sensor, enabling a 360-degree view. In at least one implementation, at least one overhead spatial sensor may be attached to a gantry rail near a top surface of process module to enable linear translation of at least one overhead spatial sensor.

In at least one implementation, spatial sensors may be electronically coupled to a computing device. In at least one implementation, motor-actuated process module components such as pedestals, slit valves, chucks, spindles, etc., are electronically coupled to a same computing device or to a second computing device that may be electronically coupled to a first computing device (e.g., computing device directly coupled to spatial sensors). In at least one implementation, an electronic control system such as shown in FIG. 8 may be employed to provide an electronic interface between the computing device and components within the process module, as well as between the computing device and spatial sensors.

In at least one implementation, at operation 1002, a teach fixture may be placed on a chuck within the process module. In at least one implementation, teach fixture comprises a ring approximately a diameter of a wafer, and spokes emanating from a hub to ring. In at least one implementation, ring may have markings and pockets for visual alignment of an end effector attached to a robot arm. In at least one implementation, teach fixture may mount on top of chuck, where alignment marks or structural features on teach fixture may be aligned with marks and structural features on chuck.

In at least one implementation, at operation 1004, a robot arm having an end effector attached to an extremity of robot arm is moved into process module. In at least one implementation, a robot arm may be stowed within a vacuum transfer module adjacent to process module, as described above. In at least one implementation, robot arm may extend through a slit valve between vacuum transfer module and process module. Robot arm motion, as well as slit valve movement, may be controlled by the computing device.

In at least one implementation, robot arm may extend end effector (e.g., a wafer paddle) to the chuck. During this operation, spatial sensors viewing through viewport windows within walls of process module may view both end effector and teach fixture edge-on. In at least one implementation, pedestal may be actuated to move vertically, guided by machine vision software obtaining the real time absolute or relative z-height position coordinates (e.g., z-coordinate relative to a reference) of end effector and/or teach fixture from edge-viewing spatial sensors.

In at least one implementation, at operation 1006, a first pinning hole on end effector may be aligned to a second pinning hole on the teach fixture. In at least one implementation, this operation may be monitored by at least one overhead spatial sensor mounted within the process module. In at least one implementation, video data from at least one overhead spatial sensor may be analyzed by computing device to determine at least x and y coordinates of first pinning hole on the end effector and the second pinning hole on teach fixture. In at least one implementation, computing device may execute software routines to guide the robot arm to align first pinning hole with second pinning hole, and to vertically position end effector over teach fixture.

In at least one implementation, at operation 1008, a dowel pin may be inserted through first pinning hole into second pinning hole. In at least one implementation, this operation may be performed manually by a user or service technician.

In at least one implementation, at operation 1010, coordinates (e.g., x and y) of first pinning hole may be obtained by machine vision and/or machine learning analysis of video data streaming from at least one overhead spatial sensor. In at least one implementation, coordinates of first pinning hole are stored in a memory. In at least one implementation, memory may be included within the computing device.

In at least one implementation, at operation 1012, end effector may be jogged (e.g., adjusted) to a z-position where, during production, a wafer carried on end effector is handed off to extended lift pins from chuck. In at least one implementation, edge-viewing spatial sensors, for example, exterior spatial sensors viewing through view port windows, may observe vertical movement of end effector relative to teach fixture. In at least one implementation, pedestal movements may also be invoked by the computing device (e.g., analyzing real-time video data) to obtain hand off z-positioning of end effector relative to the teach fixture.

In at least one implementation, at operation 1014, z-coordinate(s) for wafer hand-off position of end effector may be stored within memory. In at least one implementation, memory may be included within the computing device. In at least one implementation, system software may be trained, whereby the stored z-coordinate(s) may be recalled during subsequent autonomous wafer transfer and hand-off operations performed by the computing device during production, for example.

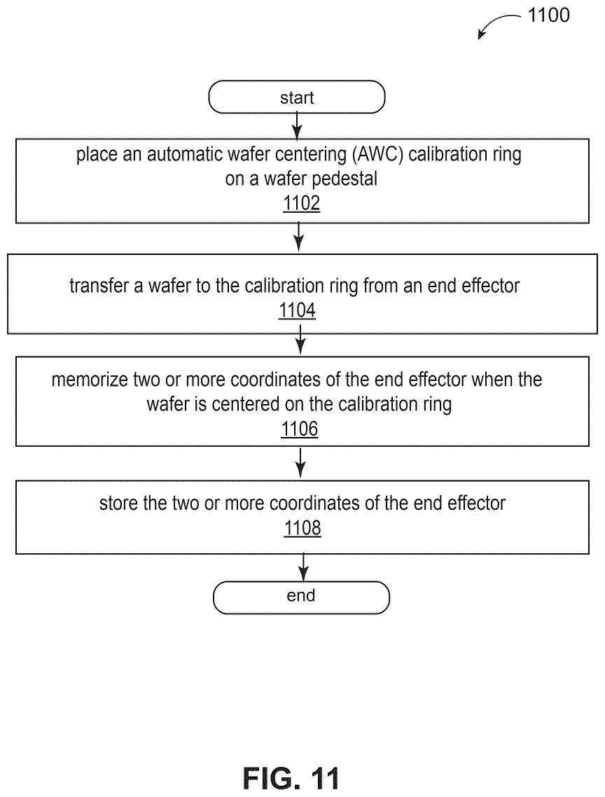

FIG. 11 illustrates flow chart 1100 summarizing an exemplary method for performing an automatic wafer centering (AWC) operation within a process module, in accordance with at least one implementation. In at least one implementation, operations of flow chart 1100 may be performed by software, hardware, or a combination of them. In at least one implementation, a process system, such as any of process systems 200, 300, and 700 disclosed herein, may comprise a process module (e.g., process module 202 or 304) comprising one or more process stations (e.g., process stations 204 and 214). In at least one implementation, process stations may comprise a showerhead, and a pedestal supporting a chuck below the showerhead. In at least one implementation, one or more spatial sensors (e.g., spatial sensors 306 and 308) may be located outside of process module. In at least one implementation, spatial sensors may be adjacent to viewport windows (e.g., viewport windows 226 and 228) within walls of the process module. In at least one implementation, viewport windows may enable spatial sensors to view chucks and/or showerheads within the process module. In at least one implementation, viewport windows are positionally fixed. In at least one implementation, pedestals may be operable to bring chucks (and wafers clamped thereon) into view of spatial sensors adjacent to viewport windows. In at least one implementation, viewport windows may be located at two or more vertical positions along walls of process module, for example, for externally located spatial sensors to monitor a wafer transfer into process module at a lower vertical level, and to monitor a PECVD process (or other deposition process), for example, at a higher vertical level within process module.

In at least one implementation, at least one overhead spatial sensors may be located within process module. In at least one implementation, at least one overhead spatial sensor may be mounted on a top wall or plate of process module to obtain overhead and/or oblique views of components within process module. In at least one implementation, at least one overhead spatial sensor may be permanently or semi-permanently located within interior of process module. In at least one implementation, at least one overhead spatial sensor may be temporarily located within the interior of process module. In at least one implementation, at least one overhead spatial sensor may be attached to a gimbal mechanism mounted on a top wall of process module for enabling swiveling and pivoting of at least one overhead spatial sensor, enabling a 360-degree view. In at least one implementation, at least one overhead spatial sensor may be attached to a gantry rail near a top surface of process module to enable linear translation of the at least one overhead spatial sensor.

In at least one implementation, at operation 1102, a calibration ring is placed on a chuck on pedestal. In at least one implementation, the calibration ring may be manually placed on chuck. In at least one implementation, calibration ring may be placed robotically. In at least one implementation, calibration ring may comprise markings and/or structural features to guide centering of a test wafer on chuck.

In at least one implementation, at operation 1104, a wafer is robotically transferred from end effector on a robot arm to calibration ring. In at least one implementation, calibration ring comprises pockets or markings to which structures on end effector may be aligned. In at least one implementation, at least one overhead spatial sensor monitors operation by capturing a video data in real time during the operation and steaming it to computing device. In at least one implementation, machine vision software and machine learning software executable by computing device may analyze video frames from video stream to dynamically determine coordinates of end effector and test wafer relative to calibration ring.

In at least one implementation, at operation 1106, centering of a test wafer on calibration ring may be determined by alignment of marks on both test wafer and calibration ring, or by determination of distances between wafer edges and structures on calibration ring. In at least one implementation, x and y coordinates of end effector may be determined when test wafer is centered. In at least one implementation, x and y coordinates of end effector may be determined by analysis of video data streaming from at least one overhead spatial sensor. In at least one implementation, z-coordinate of end effector may be observed by edge-viewing spatial sensors.

In at least one implementation, at operation 1108, x, y and z coordinates of the edge effector position when test wafer is centered may be stored in memory within computing device. In at least one implementation, x, y and z coordinates may be recalled for subsequent AWC operations.

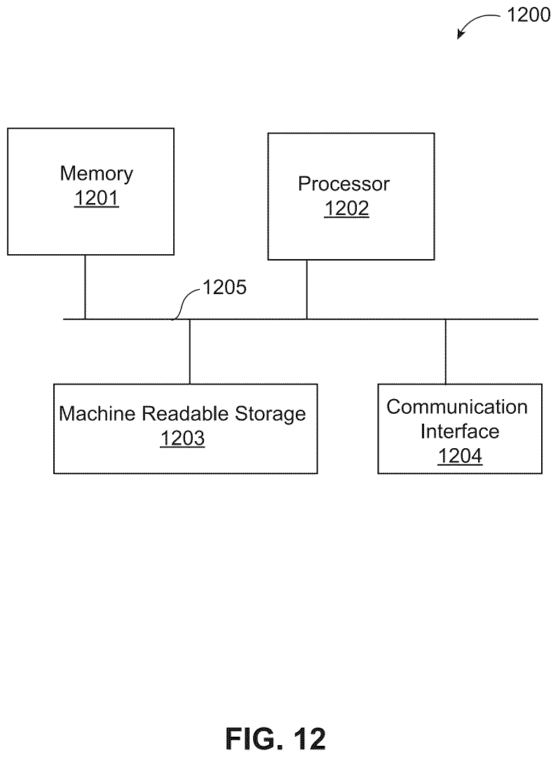

FIG. 12 illustrates processor system 1200 with machine-readable storage medium having instructions that when executed cause a processor to actuate motorized components of a process system, such as process system 700, in accordance with at least one implementation. In at least one implementation, processes described in at least one implementation, may be stored in a machine-readable storage medium 1203 as computer-executable instructions. In at least one implementation, processor system 1200 comprises memory 1201 (e.g., memory 806), processor 1202 (e.g., processor 804), machine-readable storage medium 1203 (also referred to as tangible machine-readable medium), communication interface 1204 (e.g., wireless or wired interface), and network bus 1205 coupled together as shown.

In at least one implementation, processor 1202 may be a Digital Signal Processor (DSP), an Application Specific Integrated Circuit (ASIC), a general-purpose Central Processing Unit (CPU), or a low power logic implementing a simple finite state machine to perform various processes described herein.

In at least one implementation, various logic blocks of processor system 1200 are coupled together via network bus 1205. Any suitable protocol may be used to implement network bus 1205. In at least one implementation, machine-readable storage medium 1203 includes instructions (also referred to as program software code/instructions) for enhancing ion energy and reducing ion angular spread in an inductively coupled plasma as described above with reference to various implementations.

In at least one implementation, machine-readable storage medium 1203 may be a machine-readable storage medium with instructions for programming voltage pulse to RF source coupled with an electrostatic chuck (e.g., any of chucks 208, 218, or 330 described herein). In at least one implementation, machine-readable storage medium 1203 has machine-readable instructions, that when executed, cause processor 1202 to perform methods of machine learning as discussed with reference to various implementations disclosed herein.

In at least one implementation, program software code/instructions, such as process system software associated with various process system implementations may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In at least one implementation, program software code/instructions associated with processes of various implementations are executed by processor system 1200.

In at least one implementation, program software code/instructions associated with various implementations are stored in machine-readable storage medium 1203 (e.g., memory 806) and executed by processor 1202 (e.g., processor 804). In at least one implementation, machine-readable storage medium 1203 may be a tangible machine-readable medium that can be used to store program software code/instructions and data that, when executed by a computing device, causes one or more processors (e.g., processor 804) to perform a process. In at least one implementation, process may comprise controlling an analog voltage waveform. In at least one implementation, process may comprise controlling analog voltage waveforms that are consistent with voltage signals output by robot controller 822, for example.

Referring again to FIG. 12, in at least one implementation, machine-readable storage medium 1203 may include storage of executable software program code/instructions and data in various tangible locations, including for example ROM, volatile RAM, non-volatile memory and/or cache and/or other tangible memory as referenced herein. In at least one implementation, portions of this program software code/instructions and/or data may be stored in any one of these storage and memory devices (e.g., memory 806). In at least one implementation, program software code/instructions can be obtained from other storage, including, e.g., through centralized servers or peer to peer networks and the like, including Internet. In at least one implementation, different portions of software program code/instructions and data can be obtained at different times and in different communication sessions or in a same communication session.

In at least one implementation, software program code/instructions associated with various implementations can be obtained in their entirety prior to execution of a respective software program or application. In at least one implementation, portions of software program code/instructions and data can be obtained dynamically, e.g., just in time, when needed for execution. In at least one implementation, some combination of these ways of obtaining software program code/instructions and data may occur, e.g., for different applications, components, programs, objects, modules, routines or other sequences of instructions or organization of sequences of instructions, by way of example. In at least one implementation, it may not be required that data and instructions be on a tangible machine-readable medium in entirety at a particular instance of time.

In at least one implementation, machine-readable storage medium 1203 include but are not limited to recordable and non-recordable type media such as volatile and non-volatile memory devices, read only memory (ROM), random access memory (RAM), flash memory devices, floppy and other removable disks, magnetic storage medium, optical storage medium (e.g., Compact Disk Read-Only Memory (CD ROMS), Digital Versatile Disks (DVDs), etc.), among others. In at least one implementation, software program code/instructions may be temporarily stored in digital tangible communication links while implementing electrical, optical, acoustical, or other forms of propagating signals, such as carrier waves, infrared signals, digital signals, etc. through such tangible communication links.

The following examples are provided that illustrate at least one implementation. An example can be combined with any other example. As such, at least one implementation can be combined with at least another implementation without changing the scope of the disclosure.
Example 1 is a process system comprising a vacuum transfer module; a process module having a first sidewall in common with the vacuum transfer module, wherein a pedestal comprising a wafer chuck is within the process module, and wherein at least one viewport window is within a second sidewall of the process module; at least one spatial sensor located outside of the process module, wherein a spatial sensor is adjacent to the at least one viewport window and the wafer chuck is within a field of view of the spatial sensor; and a computing device electronically coupled to the spatial sensor.
Example 2 is a process system as in any of the examples, particularly example 1, wherein the spatial sensor is a first spatial sensor, wherein a slit valve is within the first sidewall between the vacuum transfer module and the process module, wherein a second spatial sensor is attached to a slide door of the slit valve.
Example 3 is a process system as in any of the examples, particularly example 2, wherein the field of view of the first spatial sensor is a first field of view, and wherein the wafer chuck is within a second field of view of the second spatial sensor.
Example 4 is a process system as in any of the examples, particularly example 3, wherein the first field of view of the first spatial sensor is substantially orthogonal to the second field of view of the second spatial sensor wherein a first optical axis of the first spatial sensor is oriented at an angle with respect to a second optical axis of the second spatial sensor, wherein the angle ranges between zero and 180 degrees.
Example 5 is a process system as in any of the examples, particularly example 2, wherein the first spatial sensor comprises a first lens and the second spatial sensor comprises a second lens, wherein the first lens and the second lens have a first variable focal length and a second variable focal length, respectively.
Example 6 is a process system as in any of the examples, particularly example 2, wherein a third spatial sensor is mountable within the process module.
Example 7 is a process system as in any of the examples, particularly example 6, wherein the third spatial sensor is mechanically coupled to a gimbal mechanism, and wherein the gimbal mechanism is attachable to an upper wall of the process module.
Example 8 is a process system as in any of the examples, particularly example 1, wherein the computing device comprises a processor and a memory coupled to the processor, wherein the memory is configured to store a first machine-readable binary code that is executable by the processor, and wherein the first machine-readable binary code comprises one or more machine vision algorithms.
Example 9 is a process system as in any of the examples, particularly example 8, wherein the memory is configured to store a second machine-readable binary code that is executable by the processor, wherein the second machine-readable binary code comprises one or more machine learning algorithms, and wherein the one or more machine learning algorithms share data with the one or more machine vision algorithms.
Example 10 is a method comprising transferring a wafer into a process tool, wherein the process tool comprises: a vacuum transfer module; a process module having a first sidewall in common with the vacuum transfer module, wherein a pedestal comprising a wafer chuck is within the process module, and wherein at least one viewport window is within a second sidewall of the process module; a spatial sensor located outside of the process module, wherein the spatial sensor is adjacent to the at least one viewport window and the wafer chuck is within a field of view of the spatial sensor; and a computing device electronically coupled to the spatial sensor; placing a teach fixture onto the wafer chuck; moving an end effector to the pedestal; aligning the end effector to the teach fixture; and positioning the end effector by monitoring one or more coordinates of the end effector by the spatial sensor for performing a wafer handoff.
Example 11 is a method as in any of the example, particularly example 10, wherein positioning the end effector comprises monitoring one or more positional coordinates of the end effector by the spatial sensor and aligning the end effector to the teach fixture.
Example 12 is a method as in any of the examples, particularly example 11, wherein moving the end effector to the pedestal comprises monitoring by the spatial sensor and adjusting one or more positional coordinates of the end effector by the computing device while the end effector is in motion.
Example 13 is a method as in any of the examples, particularly example 12, wherein the one or more positional coordinates comprises one or more wafer-handoff coordinates, wherein the one or more wafer-handoff coordinates are retrieved by the computing device from a memory coupled to the computing device.
Example 14 is a method comprising transferring a wafer into a process tool, wherein the process tool comprises a vacuum transfer module; a process module having a first sidewall in common with the vacuum transfer module, wherein a pedestal comprising a wafer chuck is within the process module, and wherein at least one viewport window is within a second sidewall of the process module; at least one spatial sensor located outside of the process module, wherein a spatial sensor is adjacent to the at least one viewport window and the wafer chuck is within a field of view of the spatial sensor; and a computing device electronically coupled to the spatial sensor; placing the wafer onto the wafer chuck, wherein a position of the wafer on the wafer chuck is monitored by the spatial sensor; measuring an acentric offset of the wafer with respect to a reference contour; storing in a memory one or more coordinates of the acentric offset; and correcting the acentric offset by centering the wafer on the wafer chuck.
Example 15 is a method as in any of the examples, particularly example 14, wherein the spatial sensor is a first spatial sensor, wherein the first spatial sensor monitors the position of the wafer on the wafer chuck, wherein a second spatial sensor is mounted on a slit valve on the first sidewall between the vacuum transfer module and the process module, and wherein the second spatial sensor monitors the position of the wafer on the wafer chuck, wherein a first optical axis of the first spatial sensor is oriented at an angle with respect to a second optical axis of the second spatial sensor, and wherein the angle ranges from zero degrees to 180 degrees.
Example 16 is a method as in any of the examples, particularly example 15, wherein measuring the acentric offset of the wafer with respect to the reference contour comprises obtaining a first image by the first spatial sensor, obtaining a second image by the second spatial sensor, and combining the first image with the second image to build a composite image, wherein the acentric offset of the wafer in two or more dimensions is computed in the composite image.
Example 16b is a method as in any of the examples, particularly example 15, wherein the spatial sensor is a first spatial sensor, wherein the first spatial sensor monitors the position of the wafer on the wafer chuck, wherein a second spatial sensor is mounted on a side face of the first spatial sensor and offset to provide a signal of interest, and wherein the second spatial sensor monitors the position of the wafer on the wafer chuck, wherein a first optical axis of the first spatial sensor is oriented at an angle with respect to a second optical axis of the second spatial sensor, and wherein the angle ranges from zero degrees to 180 degrees. In at least one implementation, when first spatial sensor and the second spatial sensor are orthogonal relative to one another, an optimized view of the combined transformed image is generated.
Example 17 is a method as in any of the examples, particularly example 16, wherein correcting the acentric offset by centering the wafer on the wafer chuck comprises sending the acentric offset of the wafer is sent to a robot arm, wherein the robot arm is guided to move the wafer in opposition to the acentric offset.
Example 18 is a method for monitoring particle growth on a wafer under process, comprising: performing a deposition process within a process tool which comprises: a process module comprising a pedestal and a viewport window within a wall of the process module; and a spatial sensor coupled to the process module and adjacent to the viewport window, wherein the wafer is on the pedestal, wherein the wafer is within a field of view of the spatial sensor, wherein the method further comprises: collecting a video data stream from the spatial sensor; measuring a surface roughness of a film growing on the wafer; and comparing the surface roughness of the film to a threshold value.
Example 19 is a method as in any of the examples, particularly example 18, wherein collecting the video data stream from the spatial sensor comprises sending the video data stream to a computing device electronically coupled to the spatial sensor.
Example 20 is a method as in any of the examples, particularly example 19, wherein measuring the surface roughness of the film growing on the wafer comprises scanning a plurality of frames of the video data stream by the computing device.
Example 21 is a method as in any of the examples, particularly example 20, wherein comparing the surface roughness of the film to the threshold value comprises executing an algorithm by the computing device, wherein the algorithm is operable to mathematically analyze the plurality of frames of the video data stream to determine the surface roughness of the film.
Example 22 is a method as in any of the examples, particularly example 21, wherein comparing the surface roughness to the threshold value comprises detecting the particle growth by the algorithm, wherein detecting the particle growth comprises determining that the surface roughness of the film is greater than the threshold value by the algorithm.
Example 23 is a method as in any of the examples, particularly example 22, further comprising executing a cleaning operation of the process module.
Example 24 is a method as in any of the examples, particularly example 23, wherein executing the cleaning operation of the process module comprises flagging a user of the process module by the computing device to manually execute the cleaning operation of the process module.
Example 25 is a method as in any of the examples, particularly example 23, wherein executing the cleaning operation of the process module comprises autonomously executing the cleaning operation of the process module by the computing device.

Besides what is described herein, various modifications may be made to at least one implementation thereof without departing from their scope. Therefore, illustrations of at least one implementation herein should be construed as examples only, and not restrictive to the scope of the present disclosure.

We claim:

1. A process system, comprising:
a vacuum transfer module;
a process module having a first sidewall in common with the vacuum transfer module, wherein a pedestal comprising a wafer chuck is within the process module, and wherein at least one viewport window is within a second sidewall of the process module;
at least one spatial sensor located outside of the process module, wherein a spatial sensor is adjacent to the at least one viewport window and the wafer chuck is within a field of view of the spatial sensor; and
a computing device electronically coupled to the spatial sensor.

2. The process system of claim 1, wherein the spatial sensor is a first spatial sensor, wherein a slit valve is within the first sidewall between the vacuum transfer module and the process module, wherein a second spatial sensor is attached to a slide door of the slit valve.

3. The process system of claim 2, wherein the field of view of the first spatial sensor is a first field of view, and wherein the wafer chuck is within a second field of view of the second spatial sensor.

4. The process system of claim 3, wherein the first field of view of the first spatial sensor is substantially orthogonal to the second field of view of the second spatial sensor wherein a first optical axis of the first spatial sensor is oriented at an angle with respect to a second optical axis of the second spatial sensor, wherein the angle ranges between zero and 180 degrees.

5. The process system of claim 2, wherein the first spatial sensor comprises a first lens and the second spatial sensor comprises a second lens, wherein the first lens and the second lens have a first variable focal length and a second variable focal length, respectively.

6. The process system of claim 2, wherein a third spatial sensor is mountable within the process module.

7. The process system of claim 6, wherein the third spatial sensor is mechanically coupled to a gimbal mechanism, and wherein the gimbal mechanism is attachable to an upper wall of the process module.

8. The process system of claim 1, wherein the computing device comprises a processor and a memory coupled to the processor, wherein the memory is configured to store a first machine-readable binary code that is executable by the processor, and wherein the first machine-readable binary code comprises one or more machine vision algorithms.

9. The process system of claim 8, wherein the memory is configured to store a second machine-readable binary code that is executable by the processor, wherein the second machine-readable binary code comprises one or more machine learning algorithms, and wherein the one or more machine learning algorithms share data with the one or more machine vision algorithms.

10. A method comprising:
transferring a wafer into a process tool, wherein the process tool comprises:
a vacuum transfer module;
a process module having a first sidewall in common with the vacuum transfer module, wherein a pedestal comprising a wafer chuck is within the process module, and wherein at least one viewport window is within a second sidewall of the process module;
a spatial sensor located outside of the process module, wherein the spatial sensor is adjacent to the at least one viewport window and the wafer chuck is within a field of view of the spatial sensor; and
a computing device electronically coupled to the spatial sensor;
placing a teach fixture onto the wafer chuck;
moving an end effector to the pedestal;
aligning the end effector to the teach fixture; and
positioning the end effector by monitoring one or more coordinates of the end effector by the spatial sensor for performing a wafer handoff.

11. The method of claim 10, wherein positioning the end effector comprises monitoring one or more positional coordinates of the end effector by the spatial sensor and aligning the end effector to the teach fixture.

12. The method of claim 11, wherein moving the end effector to the pedestal comprises monitoring by the spatial sensor and adjusting one or more positional coordinates of the end effector by the computing device while the end effector is in motion.

13. The method of claim 12, wherein the one or more positional coordinates comprises one or more wafer-handoff coordinates, wherein the one or more wafer-handoff coordinates are retrieved by the computing device from a memory coupled to the computing device.

14. A method comprising:
transferring a wafer into a process tool, wherein the process tool comprises:
a vacuum transfer module;
a process module having a first sidewall in common with the vacuum transfer module, wherein a pedestal comprising a wafer chuck is within the process module, and wherein at least one viewport window is within a second sidewall of the process module;
at least one spatial sensor located outside of the process module, wherein a spatial sensor is adjacent to the at least one viewport window and the wafer chuck is within a field of view of the spatial sensor; and
a computing device electronically coupled to the spatial sensor;
placing the wafer onto the wafer chuck;
wherein a position of the wafer on the wafer chuck is monitored by the spatial sensor;
measuring an acentric offset of the wafer with respect to a reference contour;
storing in a memory one or more coordinates of the acentric offset; and
correcting the acentric offset by centering the wafer on the wafer chuck.

15. The method of claim 14, wherein the spatial sensor is a first spatial sensor, wherein the first spatial sensor monitors the position of the wafer on the wafer chuck, wherein a second spatial sensor is mounted on a slit valve on the first sidewall between the vacuum transfer module and the process module, and wherein the second spatial sensor monitors the position of the wafer on the wafer chuck, wherein a first optical axis of the first spatial sensor is oriented at an angle with respect to a second optical axis of the second spatial sensor, and wherein the angle ranges from zero degrees to 180 degrees.

16. The method of claim 14, wherein the spatial sensor is a first spatial sensor, wherein the first spatial sensor monitors the position of the wafer on the wafer chuck, wherein a second spatial sensor is mounted on a side face of the first spatial sensor and offset to provide a signal of interest, and wherein the second spatial sensor monitors the position of the wafer on the wafer chuck, wherein a first optical axis of the first spatial sensor is oriented at an angle with respect to a second optical axis of the second spatial sensor, and wherein the angle ranges from zero degrees to 180 degrees.

17. The method of claim 15, wherein measuring the acentric offset of the wafer with respect to the reference contour comprises obtaining a first image by the first spatial sensor, obtaining a second image by the second spatial sensor, and combining the first image with the second image to build a composite image, wherein the acentric offset of the wafer in two or more dimensions is computed in the composite image.

18. The method of claim 17, wherein correcting the acentric offset by centering the wafer on the wafer chuck comprises sending the acentric offset of the wafer is sent to a robot arm, wherein the robot arm is guided to move the wafer in opposition to the acentric offset.

19. A method for monitoring particle growth on a wafer under process, the method comprising:
performing a deposition process within a process tool which comprises:
a process module comprising a pedestal and a viewport window within a wall of the process module; and
a spatial sensor coupled to the process module and adjacent to the viewport window, wherein the wafer is on the pedestal, wherein the wafer is within a field of view of the spatial sensor, wherein the method further comprises:
collecting a video data stream from the spatial sensor;
measuring a surface roughness of a film growing on the wafer; and
comparing the surface roughness of the film to a threshold value.

20. The method of claim 19, wherein collecting the video data stream from the spatial sensor comprises sending the video data stream to a computing device electronically coupled to the spatial sensor.

21. The method of claim 20, wherein measuring the surface roughness of the film growing on the wafer comprises scanning a plurality of frames of the video data stream by the computing device, wherein comparing the surface roughness of the film to the threshold value comprises executing an algorithm by the computing device, wherein the algorithm is operable to mathematically analyze the plurality of frames of the video data stream to determine the surface roughness of the film.

22. The method of claim 21, wherein comparing the surface roughness to the threshold value comprises detecting the particle growth by the algorithm, wherein detecting the particle growth comprises determining that the surface roughness of the film is greater than the threshold value by the algorithm.

23. The method of claim 22, further comprising executing a cleaning operation of the process module.

24. The method of claim 23, wherein executing the cleaning operation of the process module comprises flagging a user of the process module by the computing device to manually execute the cleaning operation of the process module.

25. The method of claim 23, wherein executing the cleaning operation of the process module comprises autonomously executing the cleaning operation of the process module by the computing device.
